(19) United States
(12) Patent Application Publication
(10) Pub. No.: US 2016/0071877 A1
(43) Pub. Date: Mar. 10, 2016

(54) SEMICONDUCTOR DEVICES INCLUDING CELL ON PERIPHERAL EPI-SUBSTRATE AND METHODS OF MANUFACTURING THE SAME

(71) Applicants: DONG WOO KIM, INCHEON (KR); DONG KYUM KIM, SUWON-SI (KR); HUN HYEONG LIM, HWASEONG-SI (KR); JUNG GEUN LEE, SEOUL (KR)

(72) Inventors: DONG WOO KIM, INCHEON (KR); DONG KYUM KIM, SUWON-SI (KR); HUN HYEONG LIM, HWASEONG-SI (KR); JUNG GEUN LEE, SEOUL (KR)

(21) Appl. No.: 14/845,307

(22) Filed: Sep. 4, 2015

(30) Foreign Application Priority Data
Sep. 4, 2014 (KR) 10-2014-0117956

(51) Int. Cl. H01L 27/115; H01L 29/04

(52) U.S. Cl. CPC H01L 27/11582; H01L 29/04; H01L 27/11521; H01L 27/11526; H01L 27/11556; H01L 27/11568; H01L 27/11573

(57) ABSTRACT

A semiconductor device can include a single crystalline silicon substrate and a plurality of peripheral region circuits on the single crystalline silicon substrate. An insulating layer can be on the plurality of peripheral region circuits and a polycrystalline silicon substrate can be on the insulating layer, where the polycrystalline silicon substrate can include a first layer of the polycrystalline silicon substrate and an epi-second layer of the polycrystalline silicon substrate on the first layer. A plurality of memory cell circuits can be on the polycrystalline silicon substrate.

### CROSS-REFERENCE TO RELATED APPLICATION

This application claims the priority and benefit of Korean Patent Application No. 10-2014-0117956 filed on Sep. 4, 2014, with the Korean Intellectual Property Office, the disclosure of which is incorporated herein by reference.

### BACKGROUND

The present disclosure relates to a semiconductor device and a method of manufacturing the same.

Electronic products are increasingly being miniaturized, while demands are made for high capacity data processing therein. Thus, there is a need to enhance the degree of integration of semiconductor devices used in electronic products. Research has been conducted to manufacture a semiconductor device having cell and peripheral circuit regions arranged in different regions in a vertical direction.

### SUMMARY

According to an aspect of the present disclosure, a semiconductor device can include a single crystalline silicon substrate and a plurality of peripheral region circuits on the single crystalline silicon substrate. An insulating layer can be on the plurality of peripheral region circuits and a polycrystalline silicon substrate can be on the insulating layer, where the polycrystalline silicon substrate can include a first layer of the polycrystalline silicon substrate and an epi-second layer of the polycrystalline silicon substrate on the first layer. A plurality of memory cell circuits can be on the polycrystalline silicon substrate.

According to another aspect of the present disclosure, a semiconductor device can include a first region including a first substrate, a plurality of first semiconductor elements on the first substrate, and an insulating layer covering the plurality of first semiconductor elements. A second region can include a second substrate on the insulating layer and a plurality of second semiconductor elements on the second substrate. The second substrate can include a first layer on the insulating layer and as a seed layer, and a second layer can be epitaxially grown from the seed layer. An average diameter of a plurality of crystal grains included in the first layer can be larger than a thickness of the first layer.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a block diagram schematically illustrating a semiconductor device according to an exemplary embodiment in the present disclosure;

FIGS. 2A through 2C are equivalent circuit diagrams illustrating examples of a memory cell array of a semiconductor device according to exemplary embodiments in the present disclosure;

FIGS. 3 through 5 are perspective and cross-sectional views illustrating examples of a semiconductor device according to exemplary embodiments in the present disclosure;

FIG. 6 is a perspective view illustrating a semiconductor device according to an exemplary embodiment in the present disclosure;

FIGS. 7A and 7B are cross-sectional views illustrating gate dielectric layers and channel regions in semiconductor devices according to exemplary embodiments in the present disclosure;

FIGS. 8 and 9 are cross-sectional views illustrating examples of a semiconductor device according to exemplary embodiments in the present disclosure;

FIGS. 10A through 10K are cross-sectional views illustrating a method of manufacturing a semiconductor device according to an exemplary embodiment in the present disclosure;

FIGS. 11A through 11H are cross-sectional views illustrating a method of manufacturing a semiconductor device according to an exemplary embodiment in the present disclosure; and

FIGS. 12 and 13 are block diagrams illustrating examples of an electronic device including a semiconductor device according to an exemplary embodiment in the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

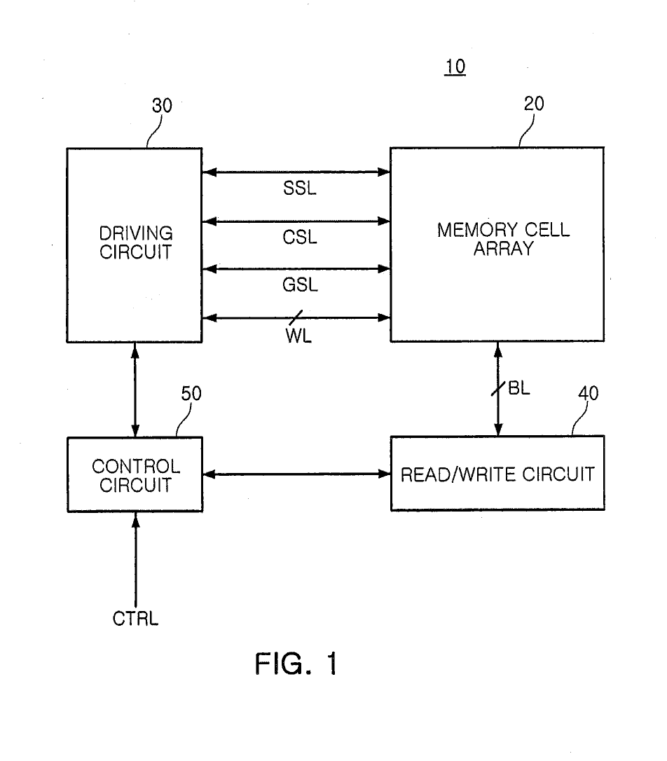

FIG. 1 is a block diagram schematically illustrating a semiconductor device according to an exemplary embodiment in the present disclosure. Here, a semiconductor device 10 according to the present exemplary embodiment may be a memory device for storing data.

Referring to FIG. 1, the semiconductor device 10 may include a memory cell array 20, a driving circuit 30, a read/write circuit 40, and a control circuit 50.

The memory cell array 20 may include a plurality of memory cells, and the plurality of memory cells may be arranged in a plurality of columns and rows. The plurality of memory cells included in the memory cell array 20 may be connected to the driving circuit 30 through at least one word line WL, at least one common source line CSL, at least one string select line SSL, at least one ground select line GSL, or the like, and may be connected to the read/write circuit 40 through at least one bit line BL. In exemplary embodiments, a plurality of memory cells arranged in the same row may be connected to the same word line WL, and a plurality of memory cells arranged in the same column may be connected to the same bit line BL.

The plurality of memory cells included in the memory cell array 20 may be divided into a plurality of memory blocks. Each of the memory blocks may include a plurality of word lines WL, a plurality of string select lines SSL, a plurality of ground select lines GSL, a plurality of bit lines BL, and at least one common source line CSL.

The driving circuit 30 and the read/write circuit 40 may be operated by the control circuit 50. In exemplary embodiments, the driving circuit 30 may receive address information from the control circuit 50, decode the received address information, and select at least some of the word lines WL, the common source lines CSL, the string source lines SSL and the ground select lines GSL connected to the memory cell array 20. The driving circuit 30 may include a driving circuit with respect to each of the word lines WL, the string select lines SSL, and the common source lines CSL.

The read/write circuit 40 may select at least one of the bit lines BL connected to the memory cell array 20 according to a command received from the control circuit 50. The read/write circuit 40 may read data stored in a memory cell connected to the selected bit line BL or write data to the memory cell connected to the selected bit line BL. In order to perform the foregoing operations, the read/write circuit 40 may include circuits such as a page buffer, an input/output buffer, and a data latch.

The control circuit 50 may control operations of the driving circuit 30 and the read/write circuit 40 in response to a control signal CTRL transmitted from outside the control circuit 50. In a case of reading data stored in the memory cell array 20, the control circuit 50 may control the operation of the driving circuit 30 to supply a voltage for a read operation to a word line in which data to be read has been stored. When the voltage for a read operation is supplied to the particular word line WL, the control circuit 50 may control the read/write circuit 40 to read data stored in a memory cell connected to the word line WL to which the voltage for a read operation has been supplied.

In a case of writing data to the memory cell array 20, the control circuit 50 may control the operation of the driving circuit 30 to supply a voltage for a write operation to a word line to which data is to be written. When the voltage for a write operation is supplied to the particular word line WL, the control circuit 50 may control the read/write circuit 40 to write data to a memory cell connected to the word line WL to which the voltage for a write operation has been applied.

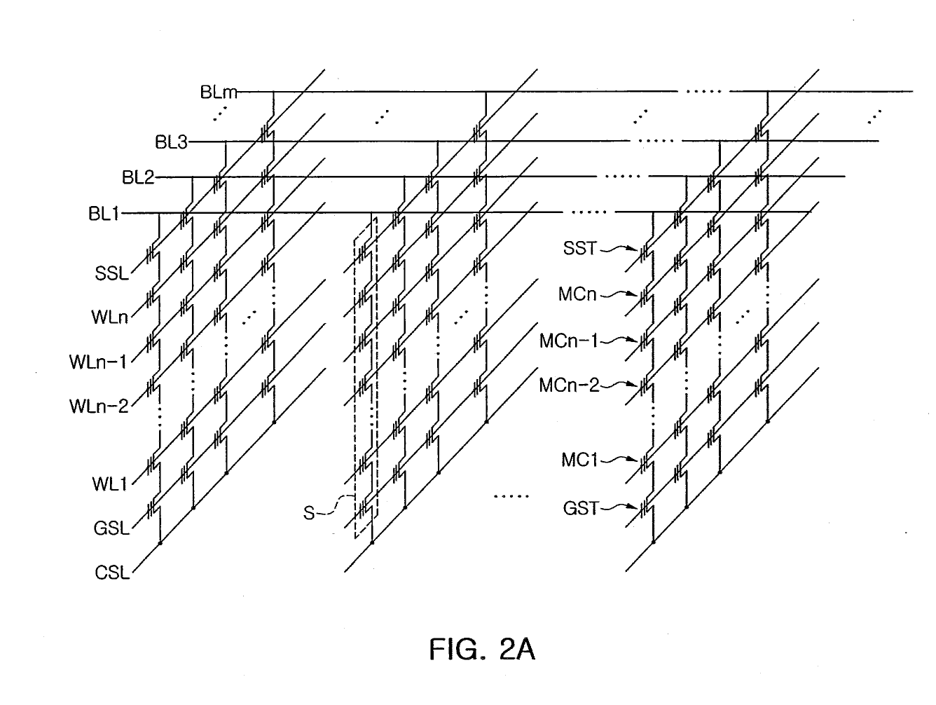

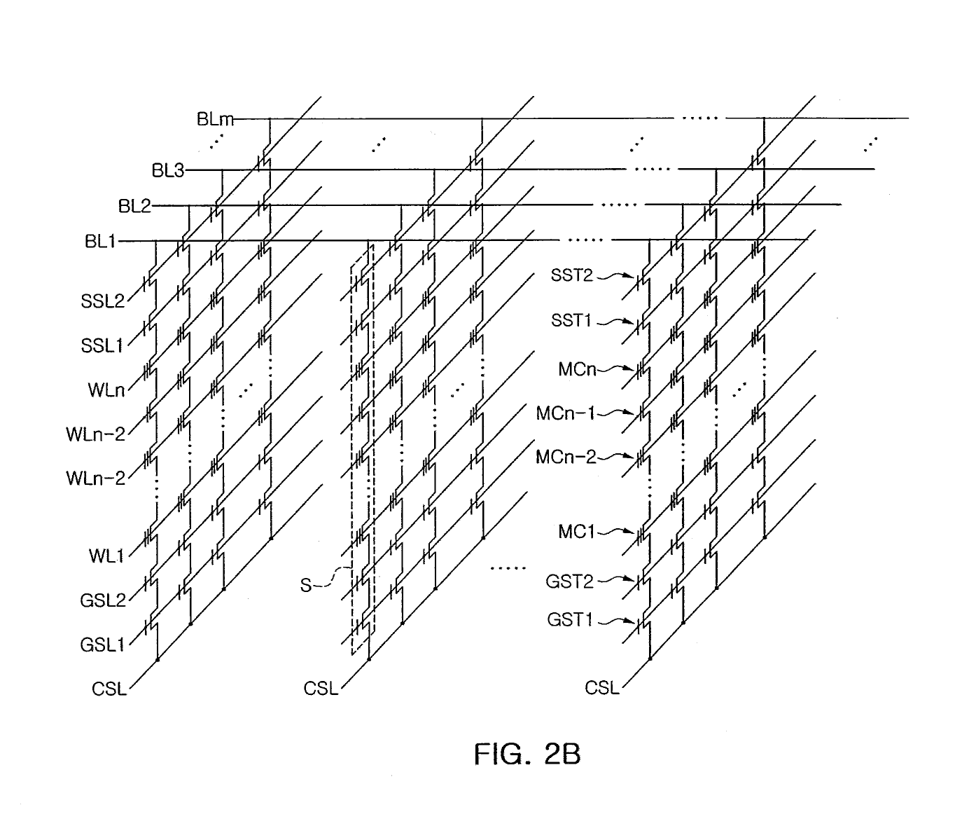

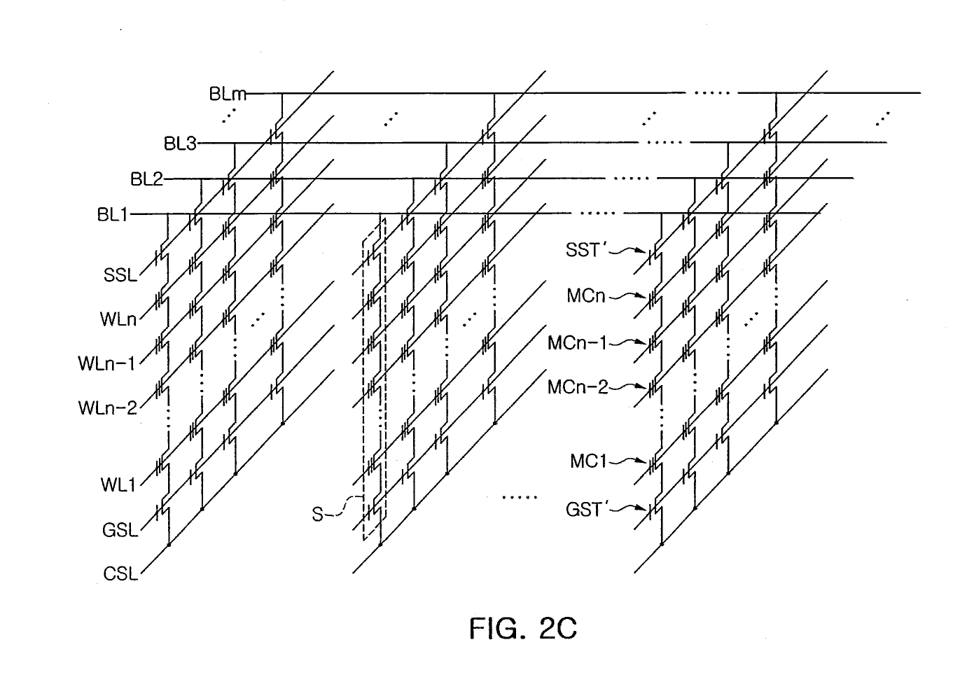

FIGS. 2A through 2C are equivalent circuit diagrams illustrating examples of a memory cell array of a semiconductor device according to exemplary embodiments in the present disclosure.

Referring to FIG. 2A, a memory cell array according to an exemplary embodiment may include a plurality of memory cell strings S, each of which may include n number of memory cells MC1 to MCn connected in series, and a ground select transistor GST and a string select transistor SST connected in series to ends of the outermost memory cells MC1 and MCn.

The n number of series-connected memory cells MC1 to MCn may be connected to the word lines WL1 to WLn, respectively, for selecting at least some of the memory cells MC1 to MCn.

A gate terminal of the ground select transistor GST may be connected to the ground select line GSL, and a source terminal thereof may be connected to the common source line CSL. Meanwhile, a gate terminal of the string select transistor SST may be connected to the string select line SSL, and a source terminal thereof may be connected to a drain terminal of the memory cell MCn. FIG. 2A illustrates a structure in which a single ground select transistor GST and a single string select transistor SST are connected to the n number of series-connected memory cells MC1 to MCn; however, a plurality of ground select transistors GST and a plurality of string select transistors SST may be connected thereto, or the structure of the ground select transistor GST or the string select transistor SST may be different from the structures of the memory cells MC1 to MCn.

For example, referring to the equivalent circuit diagram of the memory cell array illustrated in FIG. 2B, a plurality of ground select transistors GST1 and GST2 and a plurality of string select transistors SST1 and SST2 may be included in a single memory cell string S. Alternatively, referring to FIG. 2C, a ground select transistor GST′ and a string select transistor SST′ may not include a floating gate unlike the memory cells MC1 to MCn.

Generally, a drain terminal of the string select transistor SST may be connected to one of bit lines BL1 to BLn. When a signal is applied to the gate terminal of the string select transistor SST through the string select line SSL, the applied signal may be transmitted to the n number of series-connected memory cells MC1 to MCn through the bit lines BL1 to BLn to execute a data read or write operation. In addition, by applying a signal to the gate terminal of the ground select transistor GST having the source terminal connected to the common source line CSL through the gate select line GSL, an erase operation for removing all electric charges stored in the n number of memory cells MC1 to MCn may be executed.

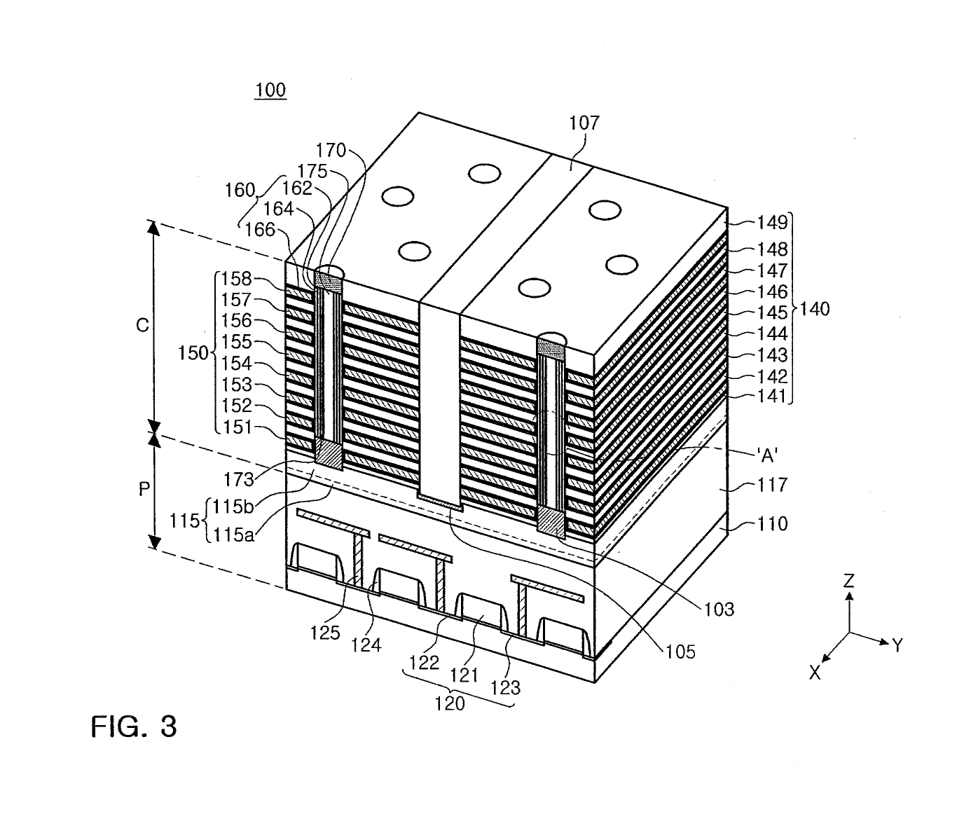

FIGS. 3 through 5 are perspective and cross-sectional views schematically illustrating examples of a semiconductor device according to exemplary embodiments in the present disclosure. Semiconductor devices 100 and 100′ according to the embodiments of FIGS. 3 through 5 are exemplified as memory devices, but are not limited thereto.

FIG. 3 is a perspective view illustrating a portion of a semiconductor device 100 according to the exemplary embodiment. Referring to FIG. 3, the semiconductor device 100 may include a first region P and a second region C. The first region P and the second region C may include a plurality of first semiconductor elements and a plurality of second semiconductor elements, respectively. In exemplary embodiments, the first region P may refer to a peripheral circuit region and the second region C may refer to a cell region. The first region P may be disposed below the second region C, in a lower portion of the device in a z-axis direction in FIG. 3, and may include a first substrate 110, a plurality of circuit elements 120 disposed on the first substrate 110, and a first insulating layer 117 covering the plurality of circuit elements 120.

The second region C may include a second substrate 115 disposed on the first region P, a channel region 173 disposed in a direction perpendicular to an upper surface of the second substrate 115, and a plurality of interlayer insulating layers 140 and a plurality of gate electrode layers 150 stacked around an outer wall of the channel region 173. In addition, the second region C may further include a gate dielectric layer 160 disposed between the plurality of gate electrode layers 150 and the channel region 173, and a buried insulating layer 175 may be disposed inside the channel region 173.

The upper surface of the first substrate 110 may be substantially parallel to the upper surface of the second substrate 115. The upper surface of the first substrate 110 and the upper surface of the second substrate 115 may be referred to as being in x-y planes in FIG. 3, and they may be substantially parallel to each other. The first substrate 110 may include a semiconductor material, such as group IV semiconductor, group III-V compound semiconductor, or group II-VI oxide semiconductor. For example, in a case in which the first substrate 110 includes group IV semiconductor, the first substrate 110 may be a silicon substrate. In addition, the first substrate 110 may be provided as a bulk wafer or an epitaxial layer.

The second substrate 115 may be disposed on the first region P. In exemplary embodiments, the second substrate 115 may be disposed on an upper surface of the first insulating layer 117 included in the first region P. Referring to FIG. 3, the second substrate 115 may include a first layer 115a disposed on the upper surface of the first insulating layer 117 and a second layer 115b disposed on the first layer 115a. The first layer 115a may be provided as a seed layer for forming the second layer 115b, and the second layer 115b may be epitaxially grown from the first layer 115a.

The first layer 115a may be a silicon layer formed by using disilane (Si₂H₆) as a silicon source, and in particular, the first layer 115a may include large-grained polycrystalline silicon. An average diameter of crystal grains included in the first layer 115a may be larger than the thickness of the first layer 115a. For example, the average diameter of the crystal grains included in the first layer 115a may be several to tens of μm. The second layer 115b may be formed by performing a selective epitaxial growth (SEG) process in which the first layer 115a is used as a seed layer. The second layer 115b may include polycrystalline silicon like the first layer 115a. An average size (e.g. diameter) of polycrystalline silicon grains included in the second layer 115b may be larger than the average size of the polycrystalline silicon grains included in the first layer 115a. Therefore, the second layer 115b may have fewer crystal defects than the first layer 115a.

The second layer 115b may be thicker than the first layer 115a. In order to provide the plurality of semiconductor elements in the second region C, a pocket P-well (PPW) may be formed within the second substrate 115. The PPW may only be formed in the second layer 115b having fewer crystal defects than the first layer 115a. Therefore, the second layer 115b may be grown to have a thickness sufficient to form the PPW. In exemplary embodiments, the thickness of the second layer 115b may be equal to or larger than 3,000 Å, which is equal to or larger than three times the thickness of the first layer 115a.

The first region P provided as the peripheral circuit region may further include metal lines 125 electrically connected to the plurality of circuit elements 120 disposed on the first substrate 110. The plurality of circuit elements 120 may each include a horizontal (i.e., planar) transistor. In this case, each circuit element 120 may include a gate electrode 121, a source electrode 122 and a drain electrode 123, and a gate spacer 124 may be provided on both lateral surfaces of the gate electrode 121. The first insulating layer 117 may include a high density plasma (HDP) oxide film in order to efficiently fill a space between the plurality of circuit elements 120. During the manufacturing of the semiconductor device 100, at least a portion of the first insulating layer 117 may be removed by using a chemical mechanical polishing (CMP) process or the like, so that the upper surface of the first insulating layer 117 may be planarized.

As illustrated in FIG. 3, in a case in which the first region P provided as the peripheral circuit region including the plurality of circuit elements 120 is disposed below the second region C provided as the cell region, the first substrate 110 used for forming the plurality of circuit elements 120 and the second substrate 115 used for forming the plurality of channel regions 173 and the plurality of gate electrode layers 150 can be formed. In a case in which the second substrate 115 is prepared after the plurality of circuit elements 120 are formed on the substrate substrate 110 and are covered with the first insulating layer 117, the second substrate 115 may be prepared by depositing polycrystalline silicon. However, the crystal grains included in the second substrate 115 may fail to grow to a sufficient size, and an angle difference between crystallization directions of adjacent crystal grains may be increased. Therefore, as appreciated by the present inventors, if many crystal defects are present within the second substrate 115, the characteristics of the ground select transistor GST formed on the second substrate 115, source regions 105 and the PPW formed in the second substrate 115 may deteriorate.

In the present exemplary embodiment, the first layer 115a including the polycrystalline silicon may be formed on the first insulating layer 117, and the second layer 115b may be formed thereon through an epitaxial growth process in which the first layer 115a is used as a seed layer. Therefore, the second layer 115b may have fewer crystal defects than the first layer 115a, and deteriorations in the characteristics of the ground select transistor GST, the source regions 105 and the PPW may be minimized.

For example, as appreciated by the present inventors, in a case in which the second substrate 115 is formed by depositing polycrystalline silicon on the first insulating layer 117 using disilane or monosilane as a silicon source, crystal grains having an angle difference of 20 to 40 degrees or 40 to 70 degrees between crystallization directions of adjacent crystal grains may account for the highest ratio. On the other hand, in a case in which the first layer 115a having polycrystalline silicon is formed by using disilane as a silicon source and the second layer 115b is formed through an epitaxial growth process by using the first layer 115a as a seed layer as in the exemplary embodiment, crystal grains having an angle difference of Q to 20 degrees between the crystallization directions of adjacent crystal grains within the second layer 115b may account for the highest ratio.

For example, within the second layer 115b formed according to the exemplary embodiment, crystal grains having an angle difference ranging from 0 degrees to less than 20 degrees between the crystallization directions of adjacent crystal grains may account for 43.2%; crystal grains having an angle difference ranging from 20 degrees to less than 40 degrees between the crystallization directions of adjacent crystal grains may account for 29.7%; and crystal grains having an angle difference of 40 degrees and more between the crystallization directions of adjacent crystal grains may account for 27.1%. Since the crystal grains having an angle difference ranging from 0 degrees to less than 20 degrees between the crystallization directions of adjacent crystal grains account for the highest ratio, crystal defects within the second layer 115b may be reduced, and deteriorations in the characteristics of the ground select transistor GST, the source regions 105 and the PPW may be minimized.

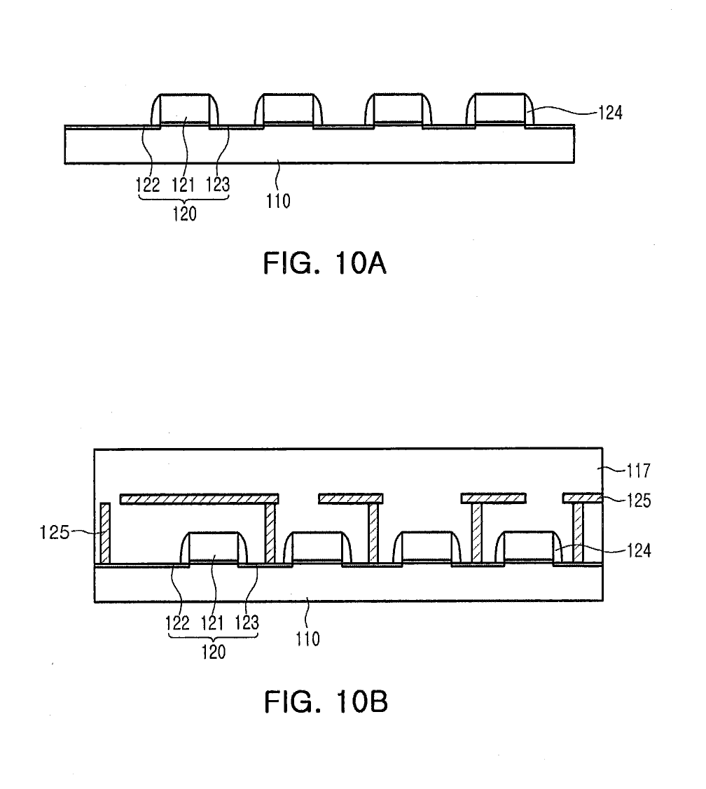

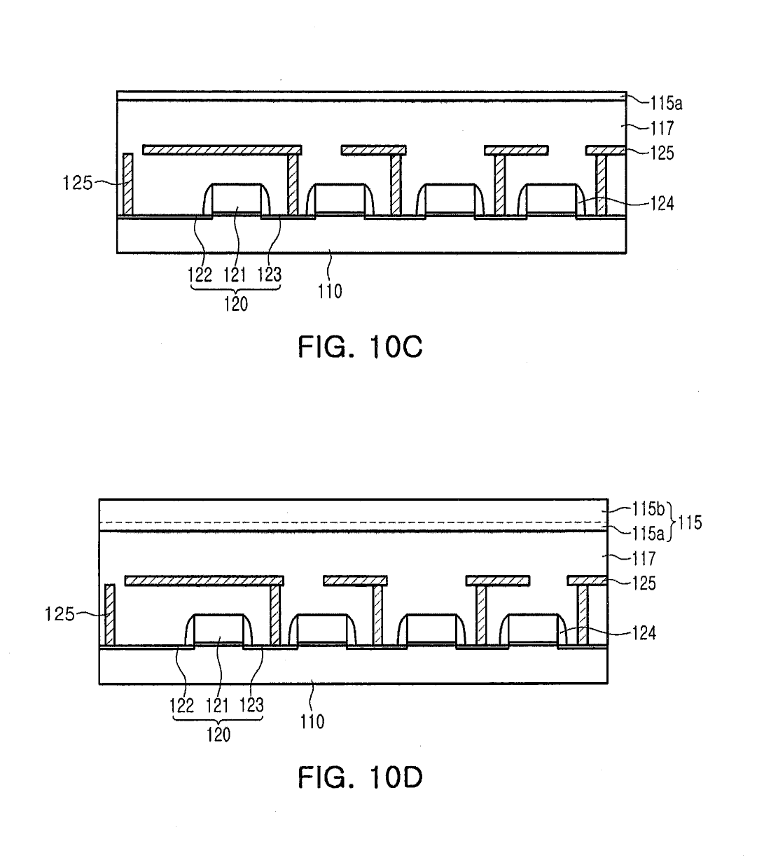

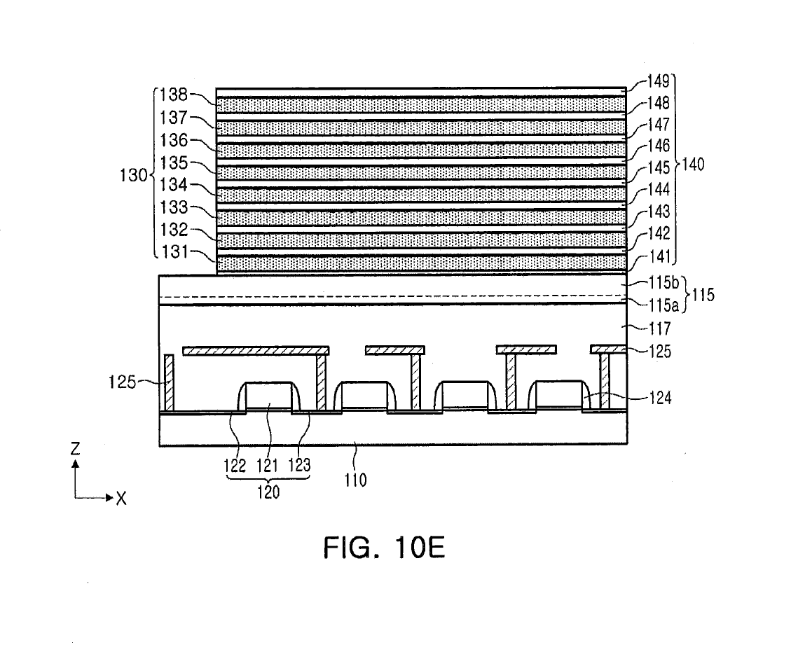

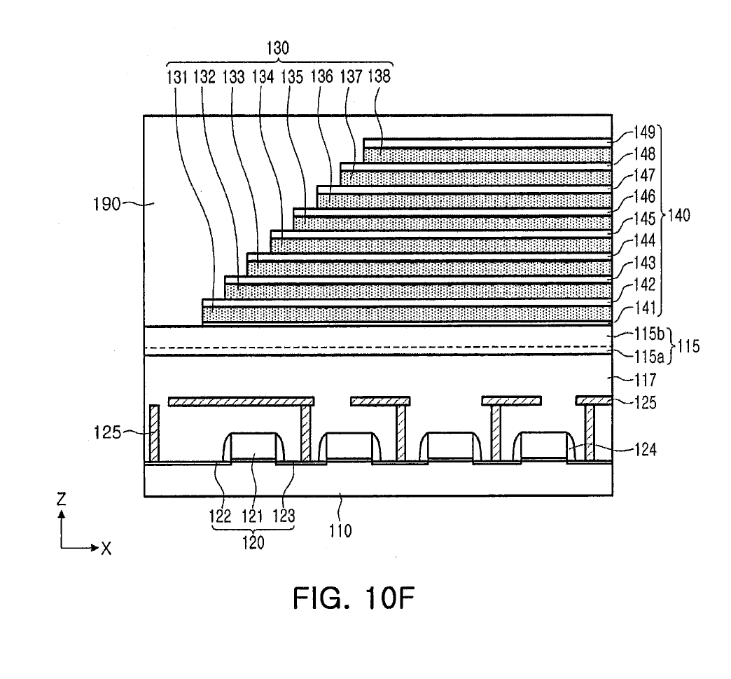

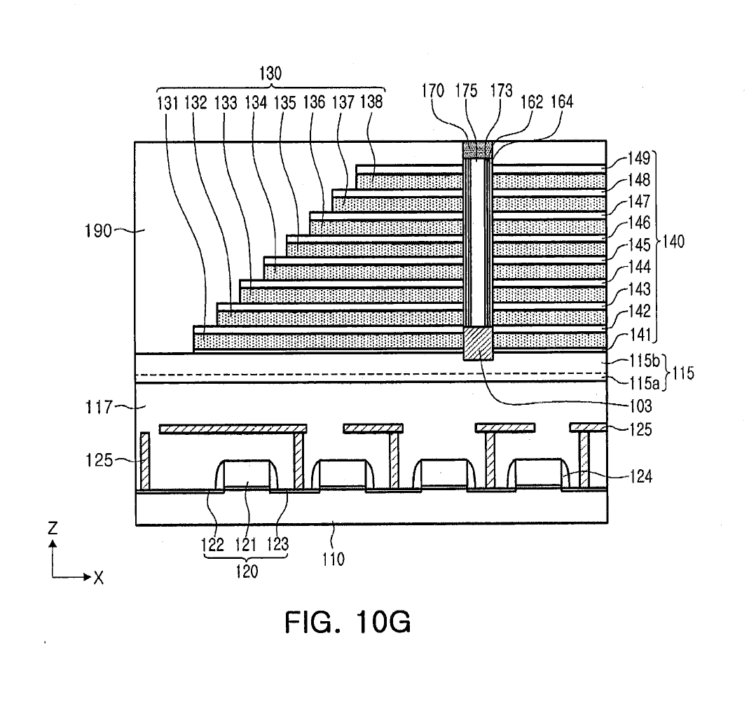

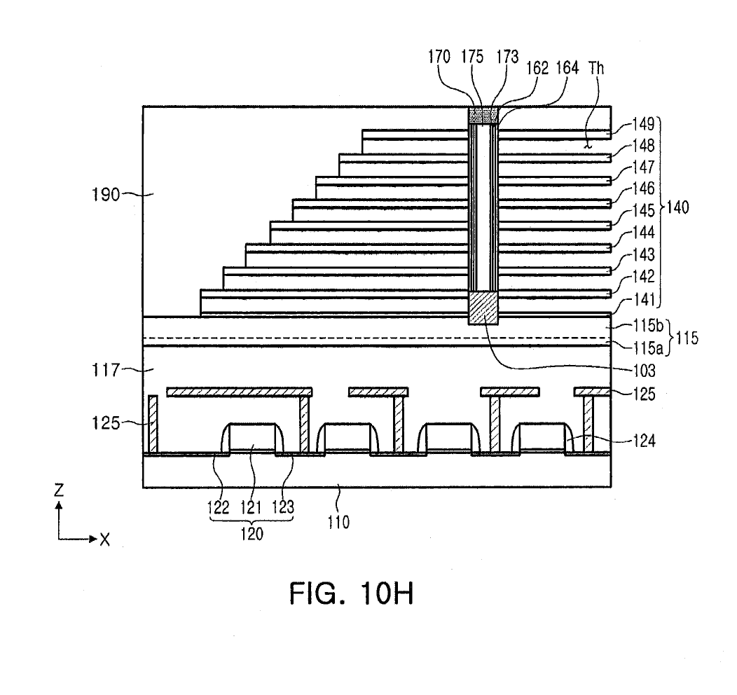

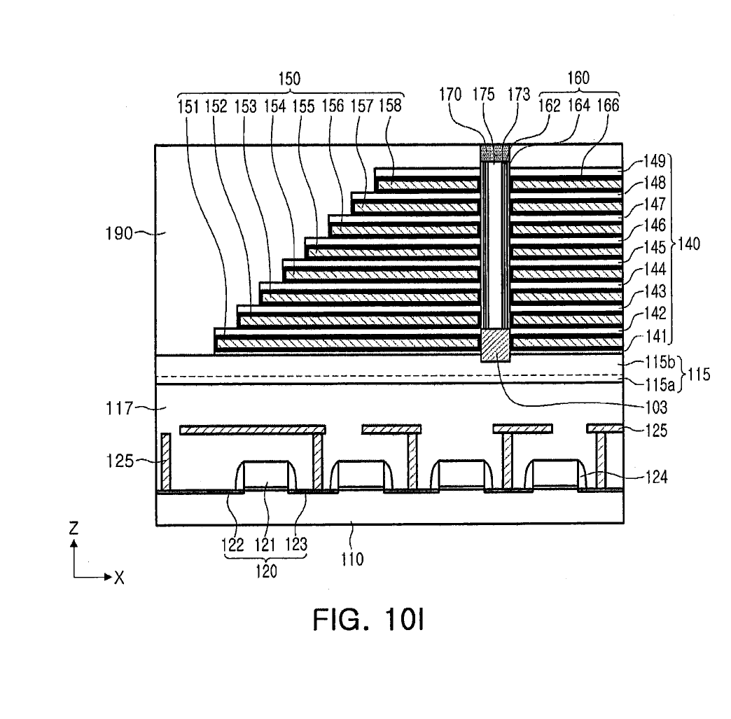

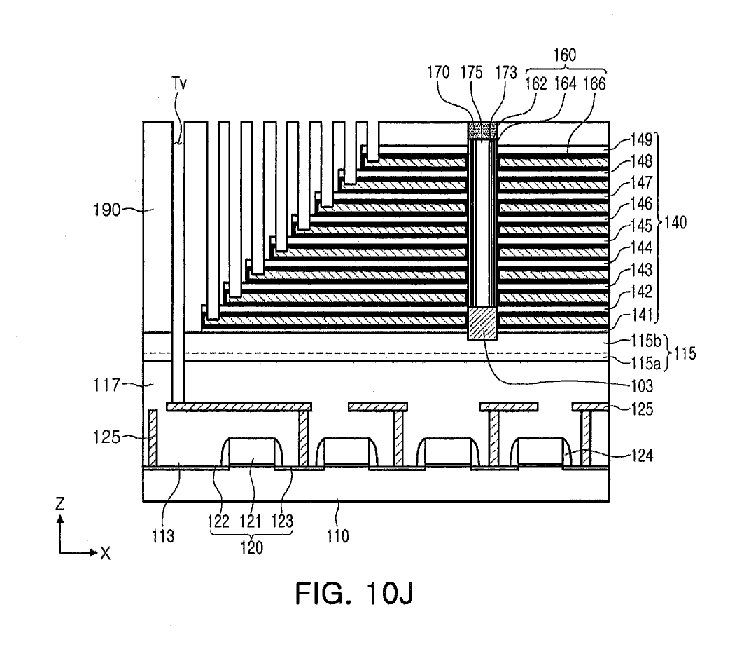

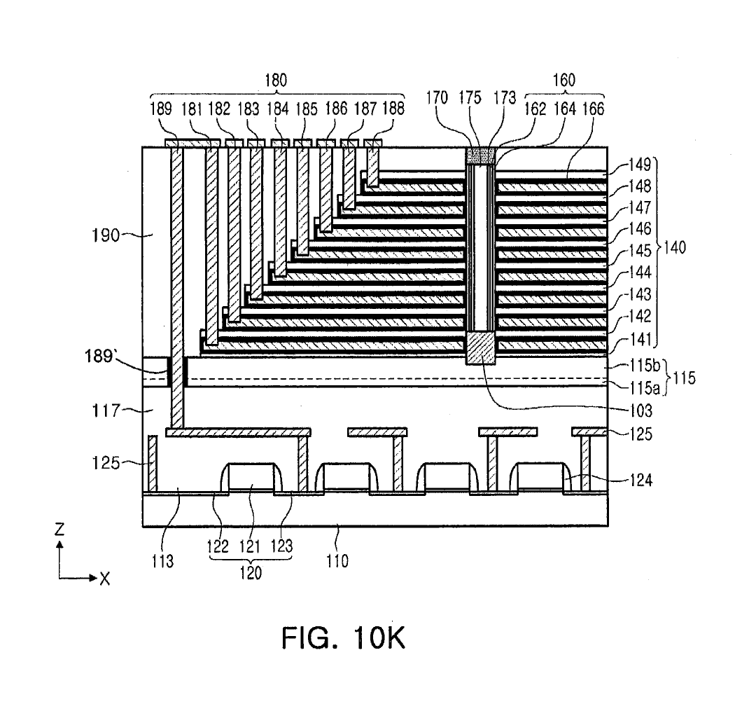

The width of the second substrate 115 may be less than that of the first substrate 110. In exemplary embodiments, an area of the second substrate 115 may correspond to or be larger than an area defined by the gate electrode layer 151 disposed in the lowermost portion of the second region C in the z-axis direction and providing the ground select transistor GST, which may help simplify a process for forming contact plugs connected to the metal lines 125 disposed in the first region P. Details thereof will be described with reference to FIGS. 10A through 10K.

The channel region 173 may be disposed on the upper surface of the second substrate 115 and extending in the direction perpendicular thereto (the z-axis direction). The channel region 173 may be formed to have the form of an annular structure surrounding the buried insulating layer 175 therein. According to exemplary embodiments, the channel region 173 may have a cylindrical or prismatic shape without the buried insulating layer 175. In addition, the channel region 173 may have an inclined lateral surface narrowed toward the second substrate 115 according to an aspect ratio thereof.

The channel regions 173 may be spaced apart from each other in the x-axis and y-axis directions. However, the arrangement of the channel regions 173 may be varied according to exemplary embodiments. For example, the channel regions 173 may be disposed in a zigzag form at least in one direction. In addition, adjacent channel regions 173 with a separation insulating layer 107 interposed therebetween may be symmetrical to each other as illustrated, but the arrangement thereof is not limited thereto.

A lower surface of the channel region 173 may contact the second substrate 115 to be electrically connected thereto. The channel region 173 may include a semiconductor material such as polysilicon or single crystal silicon. The semiconductor material may be an undoped material or may include p-type or n-type impurities. Epitaxial layers 103 may be grown through a selective epitaxial growth (SEG) process.

A plurality of gate electrode layers 151 to 158, which are collectively denoted by 150, may be disposed in parallel to the lateral surface of the channel region 173 while being spaced apart from the second substrate 115 in the z-axis direction. Referring to the perspective view of FIG. 3 together with the equivalent circuit diagram of FIG. 2A, the plurality of gate electrode layers 150 may each provide the gate terminals for the ground select transistor GST, the plurality of memory cells MC1 to MCn, and the string select transistor SST. The gate electrode layers 152 to 157 may be extended to provide the word lines WL1 to WLn, and may be connected in common to a set of adjacent memory cell strings arranged in the x-axis and y-axis directions. In exemplary embodiments, the gate electrode layers 152 to 157 provided to the memory cells MC1 to MCn are illustrated as six layers, but the number of gate electrode layers is not limited thereto. The number of gate electrode layers 152 to 157 provided to the memory cells MC1 to MCn may be determined according to the capacity of the semiconductor device 100. For example, the number of gate electrode layers 152 to 157 provided to the memory cells MC1 to MCn may be 2ⁿ (where n is a natural number).

The gate electrode layer 151 of the ground select transistor GST may provide the ground select line GSL. The gate electrode layer 158 of the string select transistor SST may provide the string select line SSL. In particular, the gate electrode layer 158 of the string select transistor SST may be divided to form different string select lines SSL between adjacent memory cell strings. According to exemplary embodiments, the gate electrode layer 158 of the string select transistor SST and the gate electrode layer 151 of the ground select transistor GST may each include two or more electrode layers and may have different structures from those of the gate electrode layers 152 to 157 of the memory cells MC1 to MCn.

The plurality of gate electrode layers 150 may include a polysilicon or metal silicide material. For example, the metal silicide material may be a silicide material including a metal selected from among cobalt (Co), nickel (Ni), hafnium (Hf), platinum (Pt), tungsten (W) and titanium (Ti). According to exemplary embodiments, the plurality of gate electrode layers 150 may include a metal material, for example, tungsten (W). In addition, the plurality of gate electrode layers 150 may further include a diffusion barrier. For example, the diffusion barrier may include at least one of tungsten nitride (WN), tantalum nitride (TaN), and titanium nitride (TiN).

A plurality of interlayer insulating layers 141 to 149, which are collectively denoted by 140, may be disposed between the plurality of gate electrode layers 150. The plurality of interlayer insulating layers 140 may be spaced apart from each other in the z-axis direction while extending in the y-axis direction, like the arrangement of the plurality of gate electrode layers 150. The plurality of interlayer insulating layers 140 may include an insulating material such as a silicon oxide or a silicon nitride.

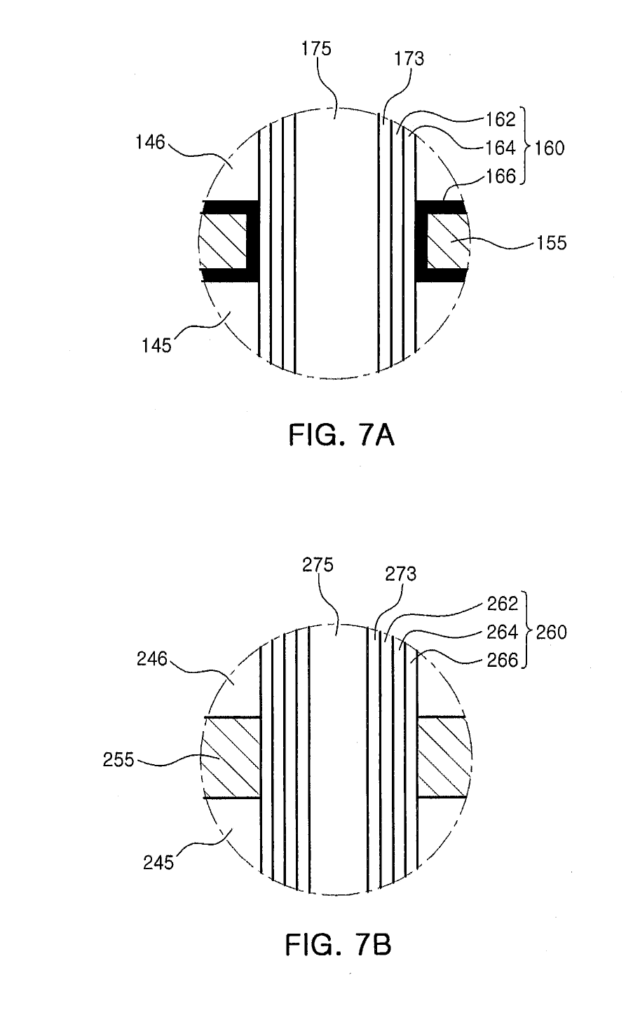

The gate dielectric layer 160 may be disposed between the plurality of gate electrode layers 150 and the channel region 173. The gate dielectric layer 160 may include a tunneling layer 162, a charge storage layer 164, and a blocking layer 166 sequentially stacked on the channel region 173, and details thereof will be provided below with reference to FIG. 7A illustrating an enlarged view of region A of FIG. 3.

The tunneling layer 162 may allow charges to tunnel to the charge storage layer 164 using the Fowler-Nordheim (F-N) tunneling mechanism. For example, the tunneling layer 162 may include a silicon oxide. The charge storage layer 164 may be a charge trapping layer or a floating gate conductive layer. For example, the charge storage layer 164 may include a dielectric material, quantum dots or nanocrystals. Here, the quantum dots or the nanocrystals may be formed of conductors, such as metals or semiconductor fine particles. The blocking layer 166 may include a high-k dielectric material. Here, the high-k dielectric material refers to a dielectric material having a dielectric constant that is greater than that of a silicon oxide.

A drain region 170 may be disposed at the top of the memory cell string to cover an upper surface of the buried insulating layer 175 and to be electrically connected to the channel region 173. For example, the drain region 170 may include doped polysilicon. The drain region 170 may serve as the drain terminal of the string select transistor SST (see FIG. 2A).

The source region 105 for each of the ground select transistors GST arranged in the x-axis direction (see FIG. 2A) may be disposed at the bottom of the memory cell string. The source region 105 may be disposed to be adjacent to the upper surface of the second substrate 115 while extending in the x-axis direction, and may be divided into unit regions spaced apart from each other in the y-axis direction. For example, a single source region 105 may be provided for every two channel regions 173 in the y-axis direction, but the arrangement thereof is not limited thereto. The separation insulating layer 107 may be formed on the source region 105.

In a case in which the conductivity of the source region 105 is opposite to that of the second substrate 115, the source region 105 may serve as the source terminals of the adjacent ground select transistors GST, and may be connected to the common source line CSL as illustrated in FIG. 2A. In a case in which the source region 105 and the second substrate 115 have the same conductivity, the source region 105 may serve as a PPW contact electrode for the erase operation in each of the memory blocks of the memory cell strings. In this case, as a high voltage is applied to the second substrate 115 through the PPW contact electrode, data stored in all memory cells of the corresponding memory block in the second substrate 115 may be erased.

Hereinafter, the gate dielectric layer 160 included in the semiconductor device 100 of FIG. 3 will be described with reference to FIG. 7A, being a partially enlarged view of region A of FIG. 3.

FIG. 7A illustrates a gate electrode layer 155, insulating layers 145 and 146, the gate dielectric layer 160 and the channel region 173 included in region A of FIG. 3. The buried insulating layer 175 may be disposed inside the channel region 173. The gate dielectric layer 160 may have a structure in which the tunneling layer 162, the charge storage layer 164, and the blocking layer 166 are sequentially stacked on the channel region 173. Relative thicknesses of the above layers forming the gate dielectric layer 160 are not limited to those illustrated in FIG. 7A, and may be varied.

The tunneling layer 162 may include at least one of a silicon oxide (SiO₂), a silicon nitride (Si₃N₄), a silicon oxynitride (SiON), a hafnium oxide (HfO₂), a hafnium silicon oxide (HfSiₓO_{y}), an aluminum oxide (Al₂O₃), and a zirconium oxide (ZrO₂).

The charge storage layer 164 may be a charge trapping layer or a floating gate conductive film. In a case in which the charge storage layer 164 is a floating gate conductive film, the charge storage layer 164 may be formed by depositing polysilicon through low pressure chemical vapor deposition (LPCVD), for example. In a case in which the charge storage layer 164 is a charge trapping layer, the charge storage layer 164 may include at least one of a silicon oxide (SiO₂), a silicon nitride (Si₃N₄), a silicon oxynitride (SiON), a hafnium oxide (HfO₂), a zirconium oxide (ZrO₂), a tantalum oxide (Ta₂O₃), a titanium oxide (TiO₂), a hafnium aluminum oxide (HfAlₓO_{y}), a hafnium tantalum oxide (HfTaₓO_{y}), a hafnium silicon oxide (HfSiₓO_{y}), an aluminum nitride (AlₓN_{y}), and an aluminum gallium nitride (AlGaₓN_{y}).

The blocking layer 166 may include a silicon oxide (SiO₂), a silicon nitride (Si₃N₄), a silicon oxynitride (SiON), or a high-k dielectric material. The high-k dielectric material may be any one of an aluminum oxide (Al₂O₃), a tantalum oxide (Ta₂O₃), a titanium oxide (TiO₂), an yttrium oxide (Y₂O₃), a zirconium oxide (ZrO₂), a zirconium silicon oxide (ZrSiₓO_{y}), a hafnium oxide (HfO₂), a hafnium silicon oxide (HfSiₓO_{y}), a lanthanum oxide (La₂O₃), a lanthanum aluminum oxide (LaAlₓO_{y}), a lanthanum hafnium oxide (LaHfₓO_{y}), a hafnium aluminum oxide (HfAlₓO_{y}), and a praseodymium oxide (Pr₂O₃). The blocking layer 166 is illustrated as including a single layer in FIG. 7A, but it may include a plurality of layers having different dielectric constants. In a case in which the blocking layer 166 includes a high-k dielectric layer and a low-k dielectric layer, the low-k dielectric layer may be disposed to contact the charge storage layer 164. The high-k dielectric layer may be formed of a material having a higher dielectric constant than that of the tunneling layer 162, and the low-k dielectric layer may be formed of a material having a relatively low dielectric constant to that of the high-k dielectric layer. By disposing the low-k dielectric layer on the side of the high-k dielectric layer, an energy band having a height equal to that of a barrier may be adjusted to improve the characteristics (e.g., erase characteristics) of the memory device.

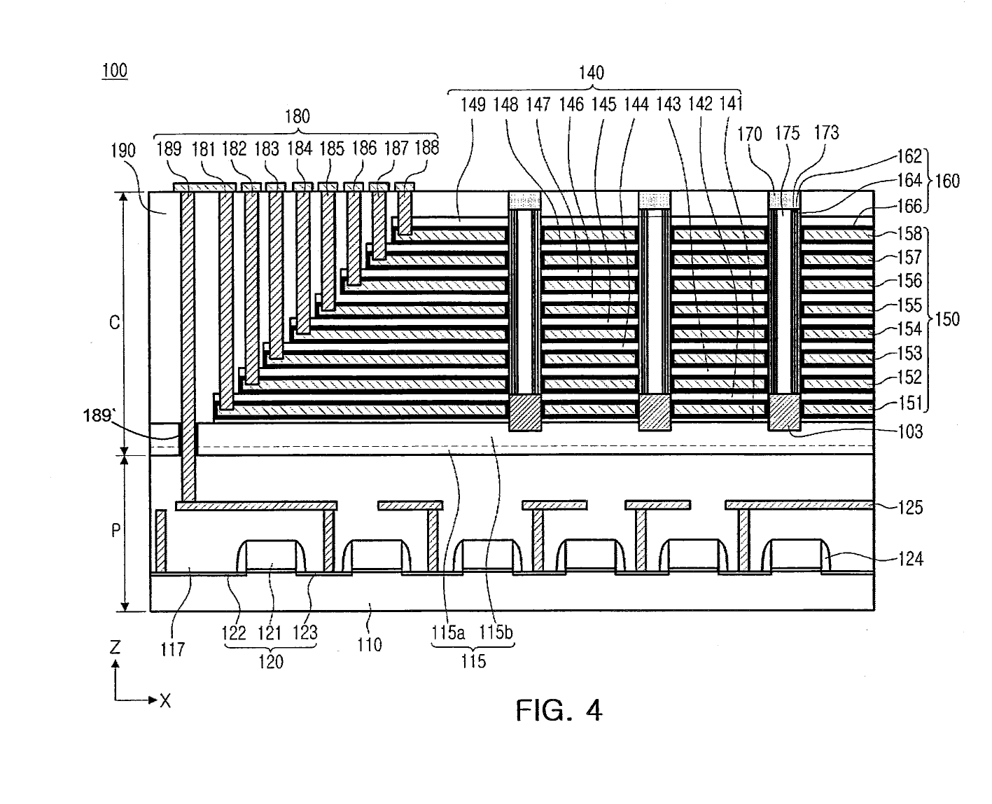

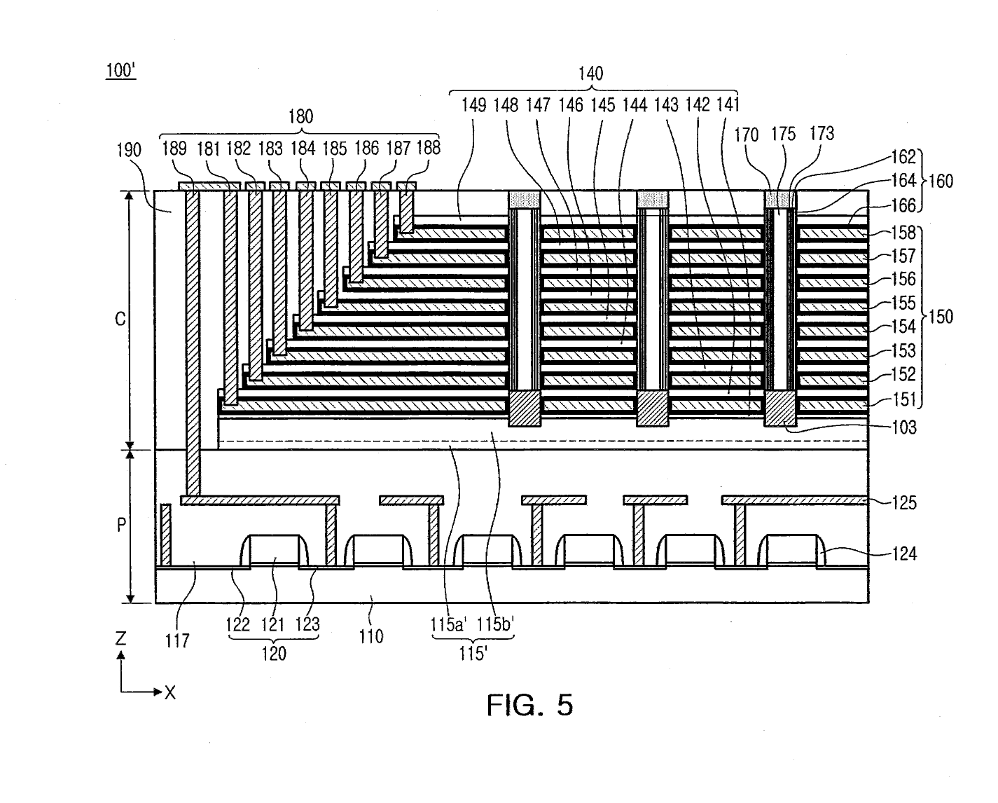

FIGS. 4 and 5 are cross-sectional views of the semiconductor device 100 of FIG. 3 viewed in the y-axis direction. In the cross-sectional view of FIG. 4, it is illustrated that the plurality of gate electrode layers 150 and the plurality of interlayer insulating layers 140 extend to have different lengths in the x-axis direction to thereby form a pad region, and a plurality of contact plugs 181 to 189, which are collectively denoted by 180, are electrically connected to the plurality of gate electrode layers 150 in the pad region and to at least one of the plurality of circuit elements 120.

Referring to FIGS. 4 and 5, the semiconductor device 100 according to the exemplary embodiment in the present disclosure may include the first substrate 110 and the second substrate 115. The first substrate 110 may be disposed below the second substrate 115. The plurality of circuit elements 120 and the metal lines 125 electrically connected to the plurality of circuit elements 120 may be disposed on the first substrate 110, and the plurality of circuit elements 120 and the metal lines 125 may be covered with the first insulating layer 117.

The second substrate 115 may be disposed on the first insulating layer 117, and the second substrate 115 may include the first layer 115a and the second layer 115b. The first layer 115a may serve as a seed layer having polycrystalline silicon, and the second layer 115b may be formed through an epitaxial growth process in which the first layer 115a is used as a seed layer. The second layer 115b may include polycrystalline silicon, and the average size of the crystal grains included in the second layer 115b may be larger than the average size of the crystal grains included in the first layer 115a.

The channel region 173 may be disposed above the second substrate 115 in the direction perpendicular to the upper surface of the second substrate 115. In addition, the plurality of gate electrode layers 150 and the plurality of interlayer insulating layers 140 may be stacked on the second substrate 115 so as to be adjacent to the channel region 173. As described above with reference to FIG. 3, the gate dielectric layer 160 may be disposed between the plurality of gate electrode layers 150 and the channel region 173, and the gate dielectric layer 160 may include the tunneling layer 162, the charge storage layer 164, and the blocking layer 166 sequentially stacked on the channel region 173.

That is, by forming the plurality of circuit elements 120 and the metal lines 125 on the first substrate 110 and forming the plurality of gate electrode layers 150 and the channel regions 173 on the second substrate 115 disposed above the first substrate 113, the semiconductor device 100 may have a cell-on-peripheral (COP) structure in which the peripheral circuit region P is disposed below the cell region C. In the semiconductor device 100 having the COP structure, the peripheral circuit region P may be reduced in the x-axis and y-axis directions, whereby the degree of integration of the semiconductor device 100 may be enhanced and the chip size may be reduced.

The plurality of gate electrode layers 150 and the plurality of interlayer insulating layers 140 may extend to have different lengths in the y-axis direction to provide the pad region, and the plurality of contact plugs 180 may be electrically connected to the plurality of gate electrode layers 150 in the pad region and to at least one of the plurality of circuit elements 120. Here, the contact plug 189 connected to at least one of the plurality of circuit elements 120 may be electrically connected to the contact plug 181 connected to the lowermost gate electrode layer 151 provided as the gate terminal of the ground select transistor GST. The plurality of metal lines 125 may include a horizontal wiring and element contacts extending from the horizontal wiring so as to be connected to the horizontal gate electrode 121, the horizontal source electrode 122 or the horizontal drain electrode 123. It is illustrated in FIG. 4 that a single metal line 125 among the plurality of metal lines is connected to the contact plug 189; however, the metal lines 125 may be connected to the other contact plugs in different positions in the y-axis direction (see FIG. 3).

The semiconductor device 100 illustrated in FIG. 4 differs from a semiconductor device 100′ illustrated in FIG. 5 in that the semiconductor devices 100 and 100′ include different second substrates 115 and 115′, respectively. An upper surface of the second substrate 115 included in the semiconductor device 100 illustrated in FIG. 4 may be larger than a lower surface of the lowermost gate electrode layer 151 adjacent to the second substrate 115. That is, in the exemplary embodiment of FIG. 4, the upper surface of the second substrate 115 may have substantially the same width or length as that of the first substrate 110 in the x-axis or y-axis direction.

In the semiconductor device 100 according to the exemplary embodiment illustrated in FIG. 4, the contact plug 189 connected to the metal lines 125 disposed in the peripheral circuit region P may penetrate through the second substrate 115 and the first insulating layer 117. Therefore, in order to connect the contact plug 189 to the metal lines 125, a second insulating layer 190 and the second substrate 115 disposed in the cell region C and the first insulating layer 117 disposed in the peripheral circuit region P may be partially etched to form a vertical opening.

An area of an upper surface of the second substrate 115′ included in the semiconductor device 100′ illustrated in FIG. 5 may correspond to an area defined by a perimeter of the lowermost gate electrode layer 151. That is, the area of the second substrate 115′ may correspond to an area of the lowermost gate electrode layer 151 in the x-axis and y-axis directions. Therefore, the upper surface of the second substrate 115′ may have a shorter width or length than that of the first substrate 110 in the x-axis or y-axis direction. In order to form the second substrate 115′ to have a smaller area than the first substrate 110, a first layer 115a provided as a seed layer may be formed on a portion of the first insulating layer 117, and polycrystalline silicon may be epitaxially grown from the first layer 115a′ to thereby form a second layer 115b′.

Unlike the semiconductor device 100 according to the exemplary embodiment illustrated in FIG. 4, the second substrate 115′ of the semiconductor device 100′ according to the exemplary embodiment illustrated in FIG. 5 does not need any etching process on the second substrate 115′ for connections between the contact plug 189 and the metal lines 125 disposed in the peripheral circuit region P. That is, a vertical opening may be formed in the first insulating layer 117 and the second insulating layer 190 formed of the same material, and may be filled with a conductive material, thereby forming the contact plug 189. Therefore, the process for forming the contact plug 189 may be simplified in the semiconductor device 100′ according to the exemplary embodiment illustrated in FIG. 5, as compared with the semiconductor device 100 according to the exemplary embodiment illustrated in FIG. 4.

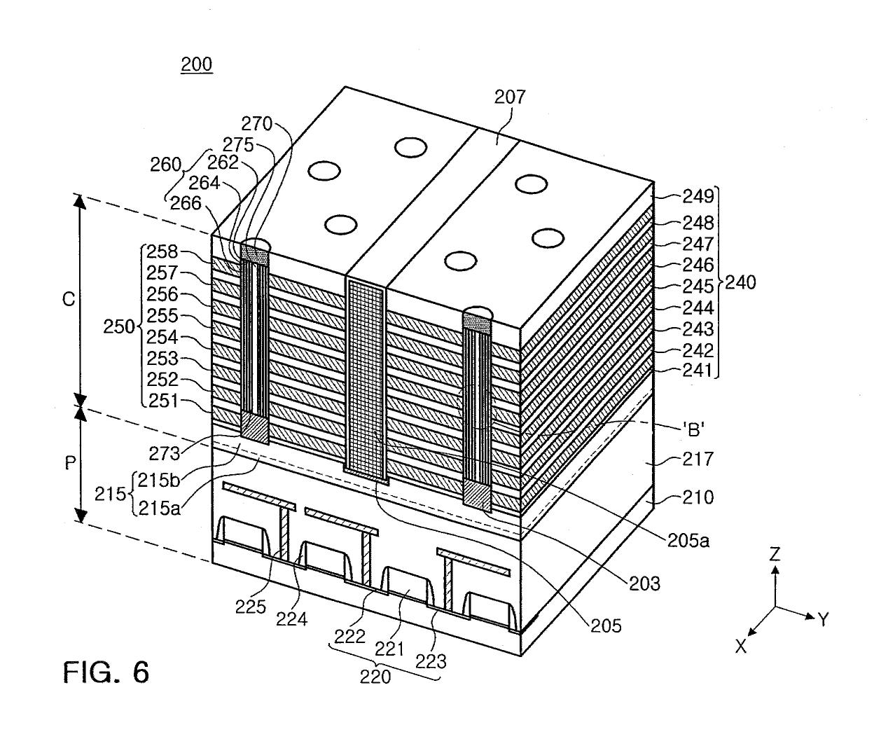

FIG. 6 is a perspective view illustrating a semiconductor device according to an exemplary embodiment in the present disclosure.

A semiconductor device 200 according to an exemplary embodiment may be a memory device having a vertical structure, in which a first region P is disposed below a second region C in a direction perpendicular thereto (a z-axis direction of FIG. 6). Referring to FIG. 6, the semiconductor device 200 according to the present exemplary embodiment may include a first substrate 210, a second substrate 215, a channel region 273, a plurality of gate electrode layers 251 to 258, which are collectively denoted by 250, a plurality of interlayer insulating layers 241 to 249, which are collectively denoted by 240, a source region 205, a buried insulating layer 207 and a gate dielectric layer 260. The first region P may be provided as a peripheral circuit region, while the second region C may be provided as a cell region.

The semiconductor device 200 illustrated in FIG. 6 may further include a common source line 205a connected to the source region 205. The bottom of the common source line 205a may be connected to the source region 205, and the common source line 205a may be electrically insulated from the plurality of gate electrode layers 250 through a separation insulating layer 207 disposed around the common source line 205a. The common source line 205a may extend in the z-axis direction on the source region 205, and may be arranged to ohmically-contact the source region 205. The common source line 205a may extend in the x-axis direction on the source region 205, and may include a conductive material. For example, the common source line 205a may include tungsten (W), aluminum (Al) or copper (Cu).

The second substrate 215 may include a first layer 215a disposed on an upper surface of the first or second insulating layer 217, 219 and a second layer 215b disposed on the first layer 215a. The first layer 215a may include polycrystalline silicon deposited on the upper surface of the first or second insulating layer 217, 219 by using disilane (Si₂H₆) as a silicon source, and may be provided as a seed layer for forming the second layer 215b. In exemplary embodiments, the first layer 215a may include large-grained polycrystalline silicon. An average diameter of the polycrystalline silicon grains included in the first layer 215a may be larger than the thickness of the first layer 215a.

The second layer 215b may include polycrystalline silicon epitaxially grown by using the first layer 215a as the seed layer, and may have relatively larger crystal grains than the first layer 215a. In addition, at least a portion of a plurality of crystal grain boundaries included in the second layer 215b may be connected to at least a portion of a plurality of crystal grain boundaries included in the first layer 215a.

In the semiconductor device 200 illustrated in FIG. 6, a gate dielectric layer 260 may be disposed between the channel region 273 and the plurality of gate electrode layers 250. The gate dielectric layer 260 may include a tunneling layer 262, a charge storage layer 264, and a blocking layer 266, and the blocking layer 266 may be formed to extend in parallel to the channel region 273, unlike the semiconductor devices 100 and 100′ illustrated in FIGS. 3 through 5. Hereinafter, the gate dielectric layer 260 will be detailed with reference to FIG. 7B.

FIG. 7B is a partially enlarged view of region B of FIG. 6.

FIG. 7B illustrates a gate electrode layer 255, interlayer insulating layers 245 and 246, the gate dielectric layer 260 and the channel region 273 included in region B of FIG. 6. A buried insulating layer 275 may be disposed inside the channel region 273. The gate dielectric layer 260 may have a structure in which the tunneling layer 262, the charge storage layer 264 and the blocking layer 266 are sequentially stacked on the channel region 273. Relative thicknesses of the above layers forming the gate dielectric layer 260 are not limited to those illustrated in FIG. 7B, and may be varied.

The blocking layer 166 is illustrated as surrounding the gate electrode layer 155 in FIG. 7A, while the blocking layer 266 is illustrated as extending in parallel to the channel region 273 in FIG. 7B. That is, in FIG. 7B, the channel region 273 may be surrounded by the tunneling layer 262, the charge storage layer 264, and the blocking layer 266. Meanwhile, materials included in the tunneling layer 262, the charge storage layer 264, and the blocking layer 266 may be similar to those in the exemplary embodiment described with reference to FIG. 7A.

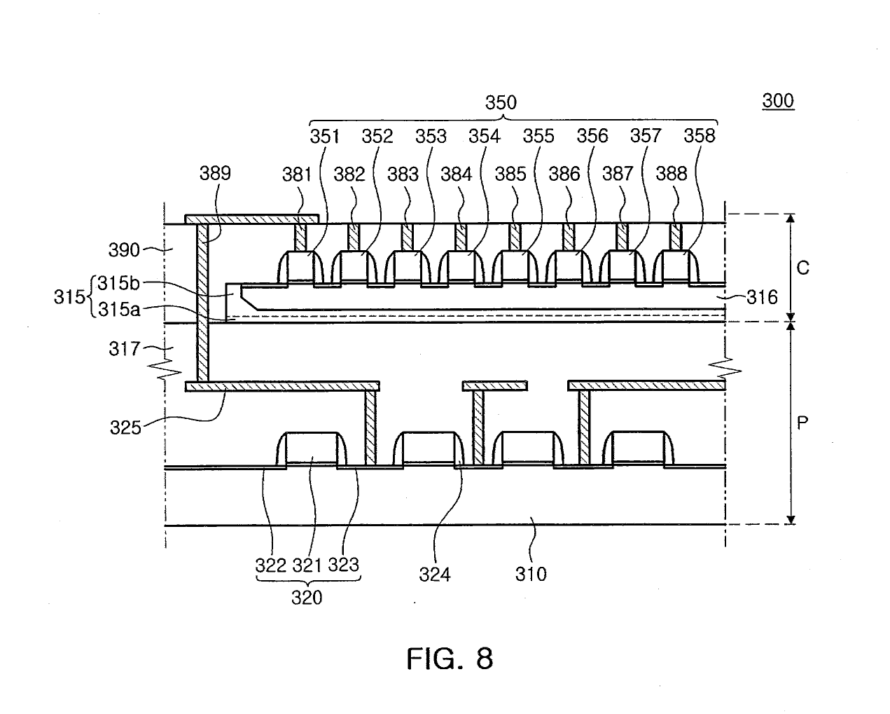

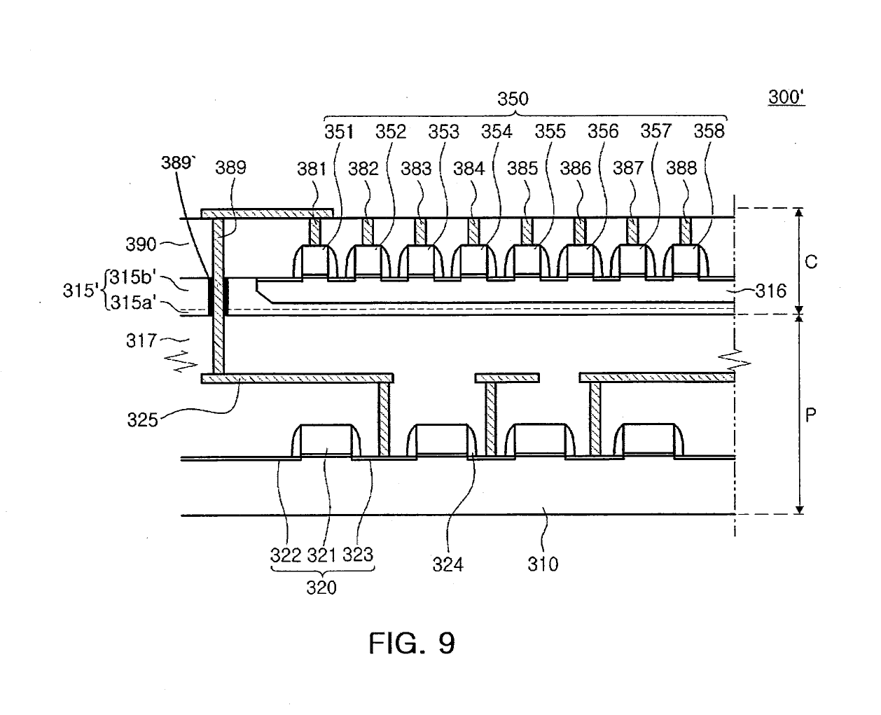

FIGS. 8 and 9 are cross-sectional views schematically illustrating examples of a semiconductor device according to exemplary embodiments in the present disclosure. In FIGS. 8 and 9, semiconductor devices 300 and 300′ according to the embodiments of the present disclosure are illustrated as memory devices having a planar structure.

The semiconductor devices 300 and 300′ illustrated in FIGS. 8 and 9 may include a first region P and a second region C disposed above the first region P in a direction perpendicular thereto. The first region P may be provided as a peripheral circuit region, while the second region C may be provided as a cell region. It is illustrated in FIGS. 8 and 9 that the first region P provided as the peripheral circuit region is disposed below the second region C provided as the cell region; however, the first region P may be disposed above the second region C.

Referring to FIG. 8, the semiconductor device 300 may include a first substrate 310, a plurality of circuit elements 320 formed on the first substrate 310, a second substrate 315, and a plurality of gate electrode layers 350 formed on the second substrate 315 and providing memory cell transistors.

The first substrate 310 may be a single crystal silicon substrate, while the second substrate 315 may be a polycrystalline silicon substrate. The second substrate 315 may include a first layer 315a disposed on an upper surface of a first insulating layer 317 covering the plurality of circuit elements 320 and a second layer 315b disposed on the first layer 315a. The first layer 315a may include polycrystalline silicon deposited on the upper surface of the first insulating layer 317 by using disilane (Si₂H₆) as a silicon source. In exemplary embodiments, the first layer 315a may include large-grained polycrystalline silicon. Meanwhile, the second layer 315b may be epitaxially grown by using the first layer 315a as a seed layer. Therefore, at least a portion of crystal grain boundaries included in the second layer 315b may be extended from at least a portion of crystal grain boundaries included in the first layer 315a.

By forming the second layer 315b through an epitaxial growth process in which the first layer 315a is used as a seed layer, an average size of the crystal grains included in the second layer 315b may be larger than an average size of the crystal grains included in the first layer 315a. In addition, an angle difference between crystallization directions of adjacent crystal grains may be reduced. For example, as appreciated by the present inventors, in a case in which the second substrate 315 is formed to include polycrystalline silicon by using disilane or monosilane (SiH₄) as a silicon source, crystal grains having an angle difference of 20 to 40 degrees or 40 to 70 degrees between crystallization directions of adjacent crystal grains may account for the highest ratio. On the other hand, in a case in which the second layer 315b is epitaxially grown by using the first layer 315a as a seed layer as in the exemplary embodiment, crystal grains having an angle difference of 0 to 20 degrees between the crystallization directions of adjacent crystal grains within the second layer 315b may account for the highest ratio. Therefore, as compared with the method of forming the polycrystalline silicon substrate by using disilane or monosilane (SiH₄) as a silicon source, the second substrate 315 may be formed to have relatively superior crystallinity and fewer crystal defects.

Meanwhile, the second layer 315b may be relatively thicker than the first layer 315a. For example, the thickness of the second layer 315b may be equal to or larger than three times the thickness of the first layer 315a or may be equal to or larger than 3,000 Å, when forming a PPW 316 within the second layer 315b of the second substrate 315. By forming the PPW 316 within the second layer 315b having relatively superior crystallinity to the first layer 315a, deterioration of operating characteristics of the memory cell transistors formed on the second substrate 315 may be reduced.

Meanwhile, in the present exemplary embodiment, the plurality of gate electrode layers 350 providing the memory cell transistors may be disposed in parallel to the upper surface of the second substrate 315. In the semiconductor device 300 according to the exemplary embodiment illustrated in FIG. 8, the PPW 316 may be formed within the second layer 315b, and the plurality of gate electrode layers 350 and source and drain electrodes arranged with the plurality of gate electrode layers 350 interposed therebetween may be formed thereon, thereby forming the memory cell transistors. The outermost gate electrode layers 351 and 358, when viewed in a direction in which the plurality of gate electrode layers 350 are arranged in parallel to each other, may be provided as a ground select transistor GST and a string select transistor SST, respectively.

The plurality of circuit elements 320 disposed on the first substrate 310 may be horizontal transistors, each of which including a gate electrode 321, a source electrode 322 and a drain electrode 323, similar to the memory cell transistors. A gate spacer 324 may be disposed on both lateral surfaces of the gate electrode 321. The plurality of circuit elements 320 may be covered with the first insulating layer 317. The first insulating layer 317 may include an HDP oxide film having excellent gap filling properties.

At least one of the plurality of circuit elements 320 may be electrically connected to at least one of the plurality of gate electrode layers 350 through at least one of metal lines 325 and contact plugs 381 to 389. Meanwhile, a source electrode of the ground select transistor GST may be connected to a common source line CSL and a drain electrode of the string select transistor SST may be connected to a bit line BL.

Referring to FIG. 8, a contact plug 389 connecting at least one of the plurality of circuit elements 320 to at least one of the plurality of gate electrode layers 350 may penetrate through a second insulating layer 390 disposed in the cell region C and the first insulating layer 317 disposed in the peripheral circuit region P. Referring to FIG. 9, at least one of the plurality of circuit elements 320 may be connected to at least one of the plurality of gate electrode layers 350 through a contact plug hole 389′ penetrating through a second substrate 315′ in addition to the second insulating layer 390 disposed in the cell region C and the first insulating layer 317 disposed in the peripheral circuit region P. In order to simplify the process for forming the contact plug 389, the first layer 315a may be formed on a portion of the upper surface of the first insulating layer 317, and the second layer 315b may be epitaxially grown from the first layer 315a, as illustrated in FIG. 8.

Hereinafter, a method of manufacturing the semiconductor device 100 illustrated in FIGS. 3 and 4 will be described with reference to FIGS. 10A through 10K.

FIGS. 10A through 10K are views illustrating a method of manufacturing the semiconductor device 100 illustrated in FIGS. 3 and 4. FIGS. 10A through 10K are cross-sectional views of FIG. 3 viewed in the x-axis direction according to a processing order.

Referring to FIG. 10A, the plurality of circuit elements 120 may be formed on the upper surface of the first substrate 110. For example, the plurality of circuit elements 120 may be horizontal transistors, each of which includes the horizontal gate electrode 121, the horizontal source electrode 122, and the horizontal drain electrode 123. The source electrode 122 and the drain electrode 123 may be formed by injecting impurities into the first substrate 110. The gate electrode 121 may be formed of polysilicon, metal, or a stack of polysilicon and metal silicide. A horizontal gate insulating film may be further provided between the gate electrode 121 and the first substrate 110, and the gate spacer 124 may be provided on the lateral surfaces of the gate electrode 121. The gate spacer 124 may be formed by depositing a silicon oxide film or the like on the gate electrode 121 through medium temperature oxidation (MTO), and applying an etch-back process thereto.

Next, referring to FIG. 10B, the plurality of circuit elements 120 may be covered with the first insulating layer 117. In order to effectively fill a space between the plurality of circuit elements 120, the first insulating layer 117 may include an HDP oxide layer having excellent gap filling properties. After the first insulating layer 117 is formed, the metal lines 125 including the horizontal wiring and the element contacts electrically connected to the plurality of circuit elements 120 may be formed in the first insulating layer 117. The first substrate 110, the plurality of circuit elements 120, the metal lines 125 and the first insulating layer 117 may define the first region P.

Referring to FIG. 10C, the first layer 115a may be formed on the upper surface of the first insulating layer 117. The first layer 115a may be a portion of the second substrate 115 for use in forming the second region C which is provided as the cell region. In particular, the first layer 115a may be used as the seed layer in the process for forming the second substrate 115. The first layer 115a may be formed through a deposition process in which disilane (Si₂H₆) is used as a silicon source, and the first layer 115a may be a polycrystalline silicon film.

The first layer 115a may be a large-grained polycrystalline silicon film. In order to form the large-grained polycrystalline silicon film, a polycrystalline silicon layer including crystal grains having a diameter of several μm may be formed on the upper surface of the first insulating layer 117 by using a solid phase crytallization (SPC) process in which a disilane gas is used as a silicon source, and the polycrystalline silicon layer may be thinned to thereby form the first layer 115a. In exemplary embodiments, the thickness of the first layer 115a may be less than the average diameter of the crystal grains included in the first layer 115a.

Then, referring to FIG. 10D, the second layer 115b may be formed by performing an epitaxial growth process in which the first layer 115a is used as the seed layer. That is, the second layer 115b may include polycrystalline silicon epitaxially grown from the first layer 115a. The second layer 115b may be thicker than the first layer 115a. In exemplary embodiments, the thickness of the second layer 115b may be equal to or greater than three times the thickness of the first layer 115a. In particular, the thickness of the second layer 115b may be greater than the depth of the PPW formed within the second substrate 115.

The average size of the crystal grains included in the second layer 115b may be larger than the average size of the crystal grains included in the first layer 115a provided as the seed layer. Therefore, the second layer 115b may have superior crystallinity to the first layer 115a. Among the crystal grains included in the second layer 115b, crystal grains having an angle difference of 0 to 20 degrees between the crystallization directions of adjacent crystal grains may account for the highest ratio. For example, crystal grains having an angle difference of 0 to 20 degrees between the crystallization directions of adjacent crystal grains included in the second layer 115b may account for 40% or more.

Referring to FIG. 10E, the plurality of interlayer insulating layers 141 to 149, which are collectively denoted by 140, and a plurality of sacrificial layers 131 to 138, which are collectively denoted by 130, may be alternately stacked on the second substrate 115. Prior to forming the plurality of interlayer insulating layers 140 and the plurality of sacrificial layers 130, chemical mechanical polishing (CMP) or the like may be performed on the upper surface of the second layer 115b.

The plurality of sacrificial layers 130 may be formed of a material that may be selectively etched as they have high etch selectivity with respect to the plurality of interlayer insulating layers 140. Etch selectivity may be expressed quantitatively by a ratio of an etch rate of the sacrificial layers 130 to an etch rate of the interlayer insulating layers 140. For example, the interlayer insulating layers 140 may be at least one of a silicon oxide film and a silicon nitride film, and the sacrificial layers 130 may be formed of a material different from that of the interlayer insulating layers 140, selected from among a silicon film, a silicon oxide film, a silicon carbide film, and a silicon nitride film. For example, in a case in which the interlayer insulating layers 140 are formed of silicon oxide films, the sacrificial layers 130 may be formed of silicon nitride films.

According to exemplary embodiments, the plurality of interlayer insulating layers 140 may have different thicknesses. For example, the lowermost interlayer insulating layer 141 among the plurality of interlayer insulating layers 140 in the z-axis direction, may be relatively thin as compared to the other interlayer insulating layers 142 to 149, and the uppermost interlayer insulating layer 149 may be relatively thick as compared to the other interlayer insulating layers 141 to 148. Namely, the thicknesses of the interlayer insulating layers 140 and the sacrificial layers 130 may be varied without being limited to those illustrated in FIG. 10E, and the number of layers of the films constituting the interlayer insulating layers 140 and the sacrificial layers 130 may also be varied.

Then, referring to FIG. 10F, the plurality of sacrificial layers 130 and the plurality of interlayer insulating layers 140 alternately stacked on the second substrate 115 may be etched to form the pad region having a step structure. In order to form the step structure between the sacrificial layers 130 and the interlayer insulating layers 140 adjacent in the z-axis direction as illustrated in FIG. 10F, predetermined mask layers may be formed on the plurality of sacrificial layers 130 and the plurality of interlayer insulating layers 140 alternately stacked on the second substrate 115, and portions of the sacrificial layers 130 and the interlayer insulating layers 140 exposed through the mask layers may be etched. By repeatedly etching the portions of the sacrificial layers 130 and the interlayer insulating layers 140 exposed through the mask layers in a plurality of times while trimming the mask layers, the sacrificial layers 130 and the interlayer insulating layers 140 may be sequentially etched to form a plurality of steps.

In exemplary embodiments, the interlayer insulating layers 140 and the sacrificial layers 130 may be paired, and the interlayer insulating layers 140 and the sacrificial layers 130 included in the plurality of pairs may extend to have substantially the same length in one direction, for example, in the y-axis direction. As an exception, an interlayer insulating layer 141 may be further disposed below the lowermost sacrificial layer 131 in the z-axis direction such that it extends to have substantially the same length. After the step structure is formed, the second insulating layer 190 may be formed on the pad region obtained by etching the portions of the interlayer insulating layers 140 and the sacrificial layers 130.

After the second insulating layer 190 is formed, the channel region 173 may be formed as illustrated in FIG. 10G. In order to form the channel region 173, an opening may be formed to penetrate through the plurality of interlayer insulating layers 140 and the plurality of sacrificial layers 130 in the z-axis direction. A plurality of openings may be provided according to the number of channel regions 173, and the plurality of openings may be disposed in a zigzag form to be spaced apart from each other on the x-y plane perpendicular to the z-axis. The plurality of openings may be formed by exposing only the portions of a mask layer corresponding to the plurality of openings to be formed, and anisotropic-etching the exposed portions, similar to the method of forming the step structure. Each of the plurality of openings may expose the upper surface of the second substrate 115 or have a predetermined depth in the second substrate 115. In order to bring the second layer 115b having relatively superior crystallinity into contact with the channel region 173, the opening for the channel region 173 may not penetrate through the second layer 115b.

The charge storage layer 164 and the tunneling layer 162 may be formed on inner and lower surfaces of each of the plurality of openings by using atomic layer deposition (ALD) or chemical vapor deposition (CVD). Here, the charge storage layer 164 and the tunneling layer 162 may be sequentially stacked on regions adjacent to the plurality of sacrificial layers 130 and the plurality of interlayer insulating layers 140, and the channel region 173 may be formed inside the tunneling layer 162. The channel region 173 may be formed to have a predetermined thickness. For example, the channel region 173 may have a thickness ranging from 1/50 to ⅕ of a width of each of the plurality of openings, and may be formed through ALD or CVD in a manner similar to that of the charge storage layer 164 and the tunneling layer 162. Meanwhile, prior to forming the charge storage layer 164 and the tunneling layer 162, the epitaxial layers 103 may be formed by performing a selective epitaxial growth (SEG) process using portions of the second substrate 115 exposed through the plurality of openings as seeds.

The interior of the channel region 173 may be filled with the buried insulating layer 175. Optionally, prior to forming the buried insulating layer 175, hydrogen annealing may be performed to heat-treat the structure of the channel region 173 under a gas atmosphere including hydrogen or heavy hydrogen. A large portion of crystal defects existing in the channel region 173 may be reduced and/or eliminated by the hydrogen annealing process.

The structure of the channel region 173 is based on FIGS. 3 and 4, but the channel region 173 may also be formed to have different structures. For example, after the plurality of openings for the channel regions are formed, each channel region 173 may be formed without performing the process of forming the charge storage layer 164, the tunneling layer 162 and the epitaxial layer 103, and the buried insulating layer 175 may be formed within the channel region 173. In this case, like the blocking layer 166, the tunneling layer 162 and the charge storage layer 164 may be formed prior to forming the gate electrode layers 150 so as to be disposed outside the blocking layer 166 while surrounding the gate electrode layers 150. In addition, there is no epitaxial layer 103, and thus the channel region 173 may directly contact the second substrate 115.

Next, a planarization process may be performed to remove unnecessary semiconductor and insulating materials covering the top of the second insulating layer 190. Thereafter, an upper portion of the buried insulating layer 175 may be removed by using an etching process, or the like, and a material for forming the conductive drain region 170 may be deposited in a position corresponding to the upper portion of the buried insulating layer 175 which has been removed. A planarization process may be performed again to form the conductive drain region 170.

After the channel region 173 is formed, the plurality of sacrificial layers 130 may be removed to form lateral openings Th as illustrated in FIG. 10H. Here, as the plurality of sacrificial layers 130 are removed, the plurality of lateral openings Th may be formed between the plurality of insulating layers 140. A conductive material may be deposited on the interior of the plurality of lateral openings Th to form the plurality of gate electrode layers 150.

Referring to FIG. 10I, the blocking layers 166 and the gate electrode layers 151 to 158, which are collectively denoted by 150, may be formed within the lateral openings Th. In forming the blocking layers 166 and the gate electrode layers 150 sequentially within the lateral openings Th, the blocking layers 166 may be formed through ALD, CVD, or physical vapor deposition (PVD), similar to the charge storage layer 164 and the tunneling layer 166. Prior to forming the gate electrode layers 150, the blocking layers 166 may be formed to surround the gate electrode layers 150 as illustrated in FIG. 10I. The gate electrode layers 150 may be formed of a conductive material such as tungsten (W).

After the blocking layers 166 and the gate electrode layers 150 are formed, an etching process may be performed in the z-axis direction parallel to the channel region 173 to form a plurality of vertical openings Tv for the contact plugs 180, as illustrated in FIG. 10J. The etching process for forming the plurality of vertical openings Tv may be performed by forming a mask layer having open regions corresponding to the vertical openings Tv and selectively etching the second insulating layer 190, the first insulating layer 117 and the plurality of interlayer insulating layers 140 with respect to the plurality of gate electrode layers 150. By selectively etching only materials included in the second insulating layer 190, the first insulating layers 117 and the plurality of interlayer insulating layers 140 with respect to a material included in the plurality of gate electrode layers 150, the vertical openings Tv may be extended to the gate electrode layers 150 and the metal line 125, as illustrated in FIG. 10J. According to exemplary embodiments, the vertical opening Tv may have a tapered structure having an inclined lateral surface so as to have a width narrowed toward the first substrate 110 due to a high aspect ratio.

At least one of the plurality of vertical openings Tv may extend to the metal line 125 disposed in the peripheral circuit region P. The corresponding vertical opening Tv extending to the metal line 125 may penetrate through the second substrate 115 in addition to the second insulating layer 190 and the first insulating layer 117.

After the mask layer for forming the plurality of vertical openings Tv is removed, the plurality of vertical openings Tv may be filled with a conductive material as illustrated in FIG. 10K, thereby forming the contact plugs 181 to 189, which are collectively denoted by 180. The contact plugs 180 may include a conductive material. For example, the contact plugs 180 may include tungsten (W), similar to the gate electrode layers 150. The contact plugs 181 to 188 connected to the gate electrode layers 150 may penetrate through the interlayer insulating layers 140 disposed on the gate electrode layers 150 in the step structure so as to be electrically connected to the gate electrode layers 150. In order to make electrical connections with the gate electrode layers 150, the vertical openings Tv for forming the respective contact plugs 181 to 188 may be extended to have depths allowing for the vertical openings Tv to penetrate through the blocking layers 162 surrounding the gate electrode layers 150. Meanwhile, the contact plug 189 electrically connected to the metal line 125 connected to at least one of the plurality of circuit elements 120 may extend from an upper surface of the second insulating layer 190 to the metal line 125. That is, the length of the contact plug 189 electrically connected to the metal line 125 may be greater than the sum of the thicknesses of the gate electrode layers 150 providing the memory cell transistors and the thicknesses of the interlayer insulating layers 140.

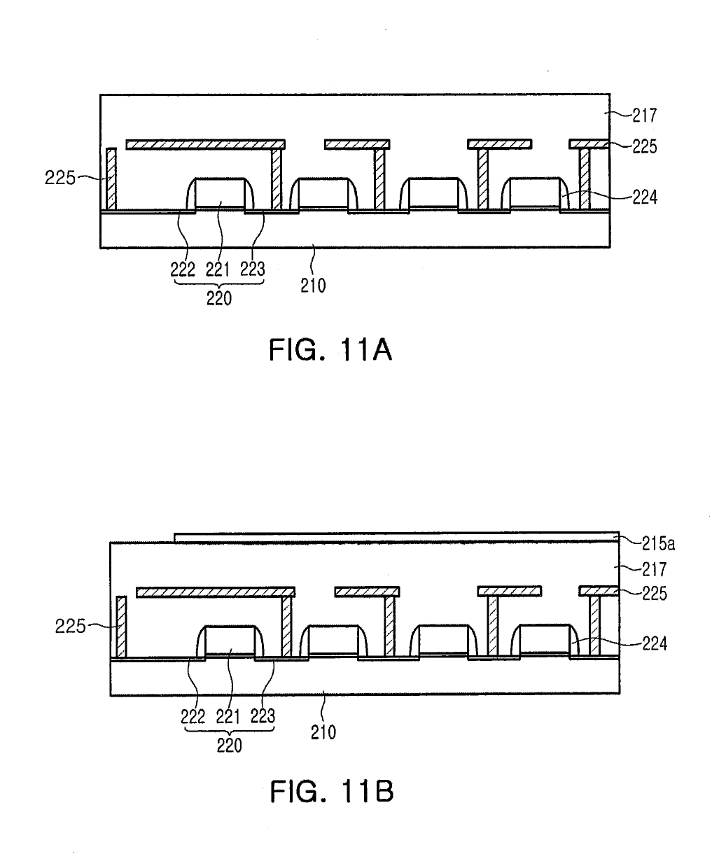

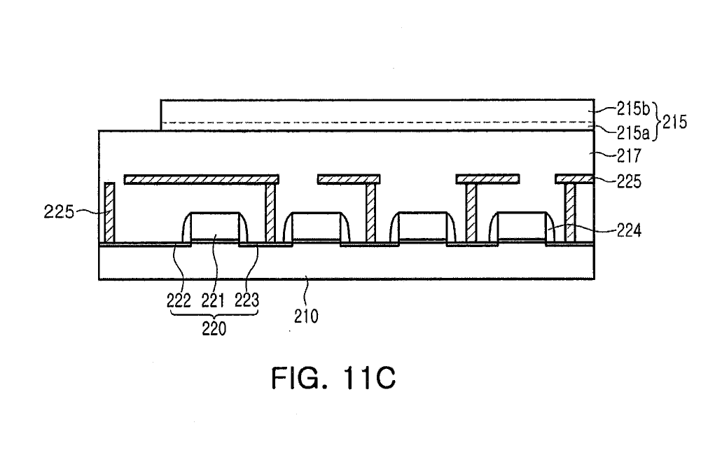

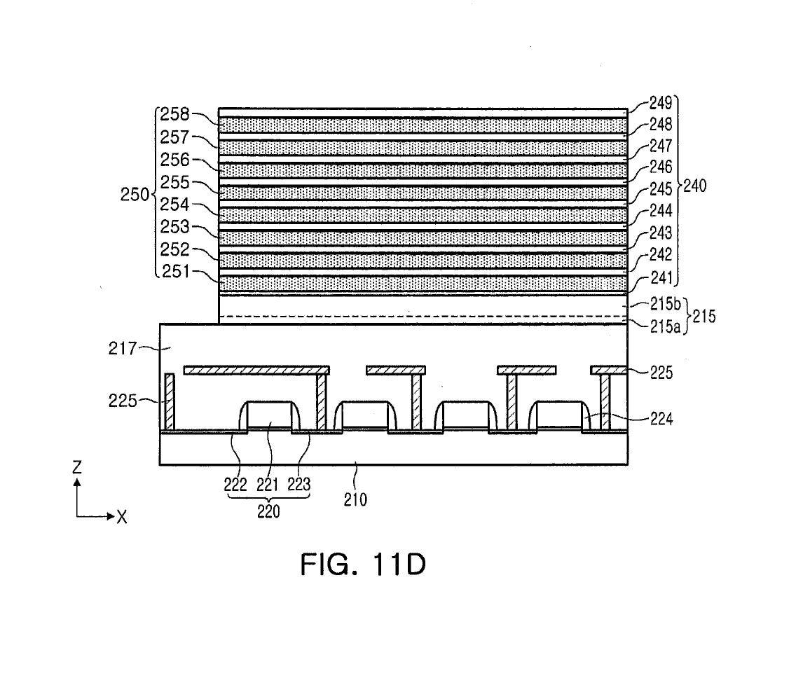

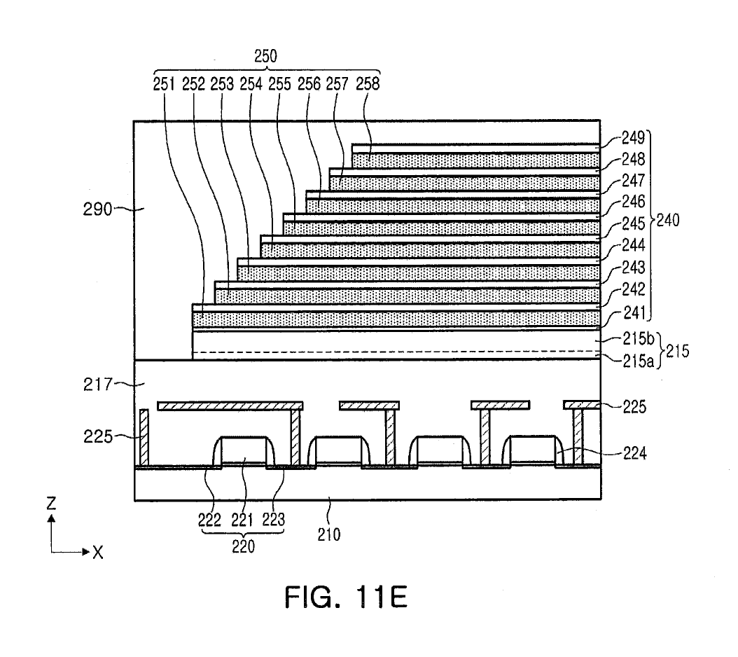

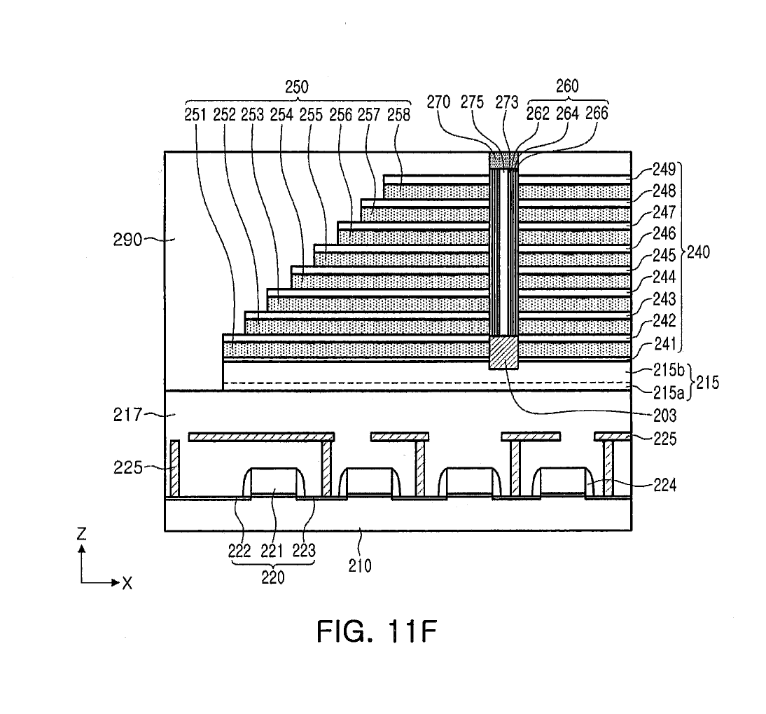

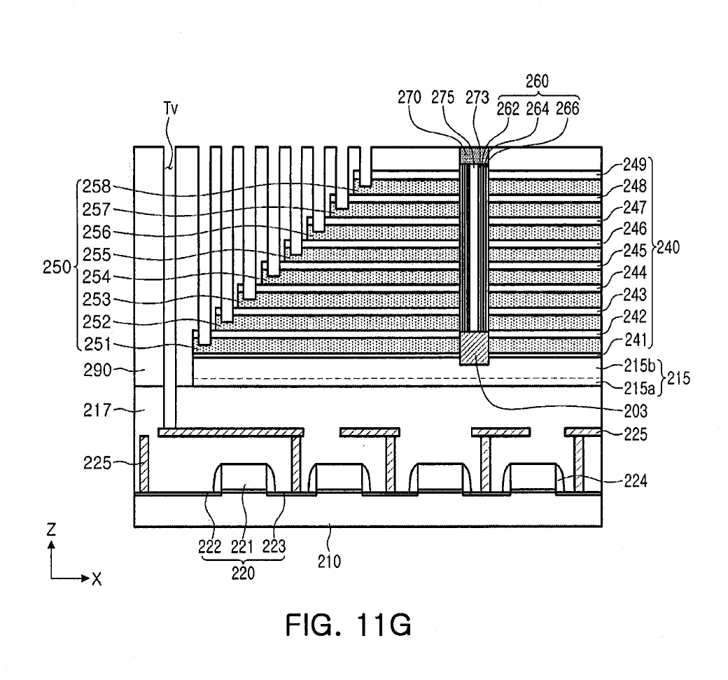

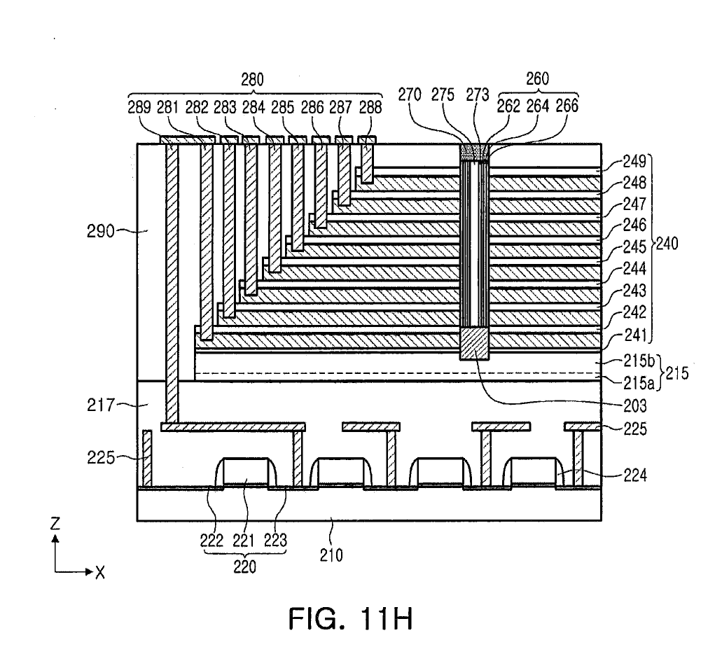

Hereinafter, a method of manufacturing the semiconductor device illustrated in FIG. 6 will be described with reference to FIGS. 11A through 11H.

FIGS. 11A through 11H are views illustrating a method of manufacturing the semiconductor device 300 illustrated in FIG. 6. FIGS. 11A through 11H are cross-sectional views of FIG. 6 viewed in the x-axis direction according to a processing order.

Referring to FIG. 11A, the first substrate 210 may be provided, and the plurality of circuit elements 220 and the first insulating layer 217 covering the plurality of circuit elements 220 may be formed on the first substrate 210. The metal lines 225 connected to at least one of the plurality of circuit elements 220 may be disposed in the first insulating layer 217. The plurality of circuit elements 220 may be horizontal transistors, each of which includes the gate electrode 221, the source electrode 222, and the drain electrode 223. The gate spacer 224 may be provided on the lateral surfaces of the gate electrode 221 of the horizontal transistor. The first insulating layer 217 may include an HDP oxide film having excellent gap filling properties, and the metal lines 225 may be formed by removing portions of the first insulating layer 217. The first substrate 210, the plurality of circuit elements 220, the metal lines 225 and the first insulating layer 217 may define the first region P.

Referring to FIG. 11B, the first layer 215a may be formed on the upper surface of the first insulating layer 217. The first layer 215a may be provided as a seed layer in preparing the second substrate 215 for use in forming the second region C which is to be provided as the cell region, and may be a large-grained polycrystalline silicon film. After polycrystalline silicon is deposited on the upper surface of the first insulating layer 217 by using a disilane gas is used as a silicon source, the polycrystalline silicon layer may be thinned to thereby form the first layer 215a. The polycrystalline silicon grains included in the first layer 215a may have an average diameter of several p.m. In exemplary embodiments, the thickness of the first layer 215a may be less than the average diameter of the crystal grains included in the first layer 215a.

In the exemplary embodiment illustrated in FIG. 11B, the first layer 215a may be formed on a portion of the upper surface of the first insulating layer 217. A portion of the first insulating layer 217 which is not covered with the first layer 215a may be used in allowing the contact plug 289, formed in a subsequent process, to be connected to the metal line 225. In order to form the first layer 215a on the portion of the upper surface of the first insulating layer 217, a seed cut process may be performed.

Next, referring to FIG. 11C, the second layer 215b may be formed through an epitaxial growth process in which the first layer 215a is used as a seed layer. The second layer 215b may include polycrystalline silicon. The average diameter of the crystal grains included in the second layer 215b may be larger than the average diameter of the crystal grains included in the first layer 215a. Since the second layer 215b is epitaxially grown by using the first layer 215a as the seed layer, at least a portion of crystal grain boundaries included in the first layer 215a may be connected to at least a portion of crystal grain boundaries included in the second layer 215b.

By forming the second layer 215b through the epitaxial growth process in which the first layer 215a, which is the large-grained polycrystalline silicon film, is used as the seed layer, the second layer 215b may be formed to have fewer crystal defects and superior crystallinity. The PPW may be formed within the second layer 215b, and the gate electrode layers 250, the source regions 205 and the channel regions 273 included in the second region C may be prepared above the second layer 215b. Therefore, due to the second layer 215b having fewer crystal defects and superior crystallinity, the gate electrode layers 250, the source regions 205 and the channel regions 273 included in the second region C may obtain improved electrical characteristics.

Referring to FIG. 11D, the plurality of gate electrode layers 251 to 258, which are collectively denoted by 250, and the plurality of interlayer insulating layers 241 to 249, which are collectively denoted by 240, may be alternately stacked on the second substrate 215. The plurality of gate electrode layers 250 may include a polysilicon or metal silicide material. For example, the metal silicide material may be a silicide material including a metal selected from among Co, Ni, Hf, Pt, W and Ti. According to exemplary embodiments, the plurality of gate electrode layers 250 may include a metal material, for example, tungsten (W). Unlike the exemplary embodiment illustrated in FIG. 10E, the plurality of gate electrode layers 250 and the plurality of interlayer insulating layers 240 may be immediately stacked on the second substrate 215, and thus the process of removing the plurality of sacrificial layers may be omitted.

Since the first layer 215a may be formed only on the portion of the upper surface of the first insulating layer 217, an area of the second substrate 215 may be substantially equal to an area of the lowermost gate electrode layer 251 and to an area of the lowermost interlayer insulating layer 241 stacked in the z-axis direction. For example, as illustrated in FIG. 11D, the second substrate 215 may have substantially the same length or width as that of the lowermost gate electrode layer 251 and the lowermost interlayer insulating layer 241 in the y-axis direction. In addition, the second substrate 215 may have substantially the same length or width as that of the lowermost gate electrode layer 251 and the lowermost interlayer insulating layer 241 in the x-axis direction.

Referring to FIG. 11E, the plurality of gate electrode layers 250 and the plurality of interlayer insulating layers 240 alternately stacked on the second substrate 215 may be etched to form the pad region having a step structure. The process of forming the pad region may be similar to the corresponding process described above with reference to FIG. 10F. In exemplary embodiments, the gate electrode layers 250 and the interlayer insulating layers 240 may be paired, and the interlayer insulating layers 240 and the gate electrode layers 250 included in the plurality of pairs may extend to have substantially the same length in one direction, for example, in the y-axis direction. After the step structure is formed, a second insulating layer 290 may be formed on the pad region.

After the interlayer insulating layer 290 is formed, the channel region 273 may be formed as illustrated in FIG. 11F. In order to form the channel region 273, an opening may be formed to penetrate through the plurality of interlayer insulating layers 240 and the plurality of gate electrode layers 250 in the z-axis direction. A plurality of openings may be provided according to the number of channel regions 273, and the plurality of openings may be disposed in a zigzag pattern spaced apart from each other on the x-y plane perpendicular to the z-axis. Each of the plurality of openings may expose the upper surface of the second substrate 215 or have a predetermined depth in the second substrate 215.

The gate dielectric layer 260 may be formed on inner and lower surfaces of each of the plurality of openings by using ALD or CVD. The gate dielectric layer 260 may include the tunneling layer 262, the charge storage layer 264, and the blocking layer 266. The blocking layer 266, the charge storage layer 264 and the tunneling layer 262 may be sequentially stacked in regions adjacent to the plurality of interlayer insulating layers 240 and the plurality of gate electrode layers 250, and the channel region 273 may be formed inside the tunneling layer 262. The channel region 273 may be formed through ALD or CVD, similar to the gate dielectric layer 260. Meanwhile, prior to forming the gate dielectric layer 260, epitaxial layers 203 may be formed using an SEG process using regions of the second substrate 215 exposed through the plurality of openings as seeds.

The interior of the channel region 273 may be filled with the buried insulating layer 275. Optionally, prior to forming the buried insulating layer 275, hydrogen annealing may be performed to heat-treat the structure of the channel region 273 under a gas atmosphere including hydrogen or heavy hydrogen. A large portion of crystal defects existing in the channel region 273 may be reduced and/or eliminated by the hydrogen annealing process.

A planarization process may be performed to remove unnecessary semiconductor and insulating materials covering the top of the second insulating layer 290. Thereafter, an upper portion of the buried insulating layer 275 may be removed by using an etching process, or the like, and a material for forming a conductive drain region 270 may be deposited in a position corresponding to the upper portion of the buried insulating layer 275 which has been removed. A planarization process may be performed again to form the conductive drain region 270.

After the channel region 273 is formed, portions of the second insulating layer 290 and the plurality of interlayer insulating layers 240 may be etched in the pad region to form a plurality of vertical openings Tv as illustrated in FIG. 11G. The vertical openings Tv are to form contact plugs, and may be formed by disposing a mask layer having open regions corresponding to the vertical openings Tv and selectively etching portions of the second insulating layer 290, the first insulating layer 217 and the plurality of interlayer insulating layers 240 with respect to the plurality of gate electrode layers 250. Meanwhile, the vertical opening Tv may have a tapered structure having an inclined lateral surface so as to have a width narrowed toward the substrate 210 due to a high aspect ratio.

Since the second substrate 215 may be formed only on the portion of the upper surface of the first insulating layer 217, at least one of the vertical openings Tv connected to the metal line 225 may not need to penetrate through the second substrate 215. That is, the corresponding vertical opening Tv connected to the metal line 225 may be formed to extend to the metal line 225 by etching only portions of the second insulating layer 290 and the first insulating layer 217. Therefore, the process of forming the vertical opening Tv may be simplified as compared with the corresponding process illustrated in FIG. 10J.

After the mask layer for forming the plurality of vertical openings Tv is removed, the plurality of vertical openings Tv may be filled with a conductive material as illustrated in FIG. 11H, thereby forming the contact plugs 281 to 289, which are collectively denoted by 280. The contact plugs 280 may include a conductive material. For example, the contact plugs 280 may include tungsten (W), similar to the gate electrode layers 250. The contact plugs 281 to 288 connected to the gate electrode layers 250 may penetrate through the interlayer insulating layers 240 disposed on the gate electrode layers 250 in the step structure so as to be electrically connected to the gate electrode layers 250. In order to make electrical connections with the gate electrode layers 250, the vertical openings Tv for forming the respective contact plugs 281 to 288 may be extended to have predetermined depths in the gate electrode layers 250. Meanwhile, the contact plug 289 electrically connected to the metal line 225 connected to at least one of the plurality of circuit elements 220 may extend from an upper surface of the second insulating layer 290 to the metal line 225. That is, the length of the contact plug 289 electrically connected to the metal line 225 may be greater than the sum of the thicknesses of the gate electrode layers 250 providing the memory cell transistors and the thicknesses of the interlayer insulating layers 240.

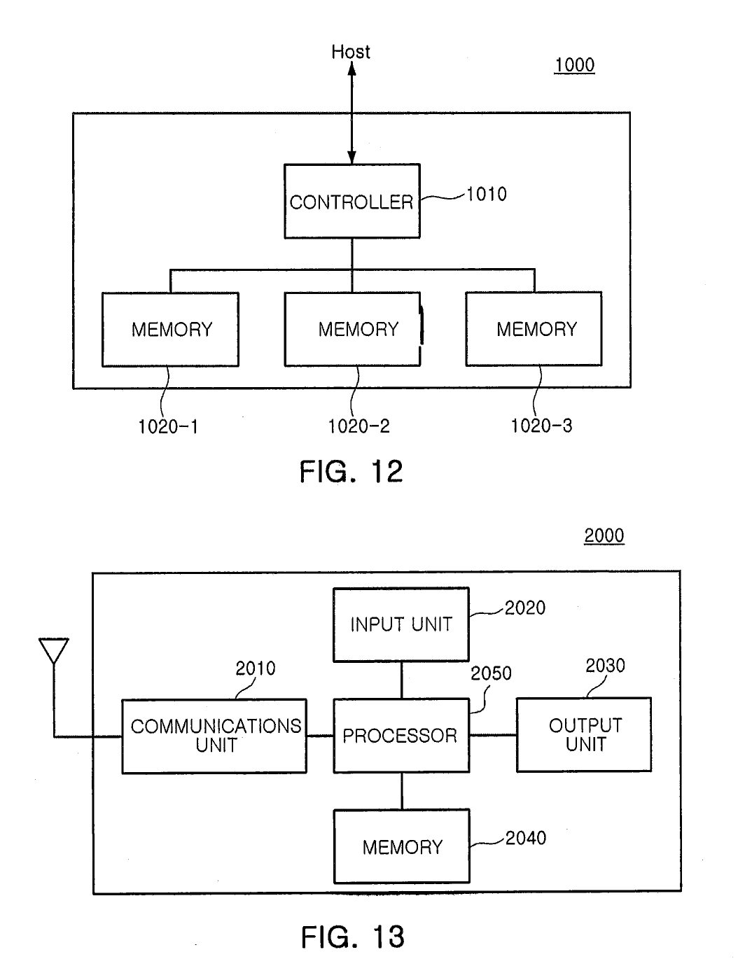

FIGS. 12 and 13 are block diagrams illustrating examples of an electronic device including a semiconductor device according to an exemplary embodiment in the present disclosure.

FIG. 12 is a block diagram illustrating a storage device including a semiconductor device according to an exemplary embodiment in the present disclosure.

Referring to FIG. 12, a storage device 1000 according to this exemplary embodiment may include a controller 1010 communicating with a host HOST and memories 1020-1, 1020-2, and 1020-3 storing data. Each of the memories 1020-1, 1020-2, and 1020-3 may include at least one of the semiconductor devices according to the exemplary embodiments described above with reference to FIGS. 3 through 9.

The host HOST communicating with the controller 1010 may be various electronic devices in which the storage device 1000 is installed or coupled. For example, the host HOST may be a smartphone, a digital camera, a desktop computer, a laptop computer, a media player, or the like. When a data write or read request is received from the host HOST, the controller 1010 may store data in the memories 1020-1, 1020-2, and 1020-3 or generate a command CMD to retrieve data from the memories 1020-1, 1020-2, and 1020-3.

As illustrated in FIG. 12, one or more memories 1020-1, 1020-2, and 1020-3 may be connected to the controller 1010 in parallel within the storage device 1000. By connecting the plurality of memories 1020-1, 1020-2, and 1020-3 to the controller 1010 in parallel, the storage device 1000 having large capacity, such as a solid state drive (SSD), may be provided.

FIG. 13 is a block diagram illustrating an electronic device including a semiconductor device according to an exemplary embodiment in the present disclosure.

Referring to FIG. 13, an electronic device 2000 according to this example embodiment may include a communications unit 2010, an input unit 2020, an output unit 2030, a memory 2040, and a processor 2050.

The communications unit 2010 may include a wired/wireless communications module, and may include a wireless Internet module, a short-range communications module, a global positioning system (GPS) module, a mobile communications module, or the like. The wired/wireless communications module included in the communications unit 2010 may be connected to an external communication network based on various communication standards to transmit and receive data.

The input unit 2020, provided to allow a user to control operations of the electronic device 2000, may include a mechanical switch, a touchscreen, a voice recognition module, and the like. Also, the input unit 2020 may include a mouse operating in a track ball or a laser pointer manner, or the like, or a finger mouse. In addition, the input unit 2020 may further include various sensor modules allowing the user to input data.

The output unit 2030 may output information processed in the electronic device 2000 in an audio or video format, and the memory 2040 may store a program for processing and controlling of the processor 2050, data, or the like. The memory 2040 may include at least one of the semiconductor devices according to the exemplary embodiments as described above with reference to FIGS. 3 through 9. The processor 2050 may deliver a command to the memory 2040 to store data to the memory 2040 or retrieve data therefrom.

The memory 2040 may be installed in the electronic device 2000 or communicate with the processor 2050 through a separate interface. In a case in which the memory 2040 communicates with the processor 2050 through a separate interface, the processor 2050 may store data to the memory 2040 or retrieve data therefrom through various interface standards such as SD, SDHC, SDXC, MICRO SD, or USB.

The processor 2050 controls operations of respective units included in the electronic device 2000. The processor 2050 may perform controlling and processing related to an audio call, a video call, data communications, and the like, or may perform controlling and processing for multimedia playback and management. Also, the processor 2050 may process input from the user through the input unit 2020 and output corresponding results through the output unit 2030. Further, the processor 2050 may store data used for the operation of the electronic device 2000 in the memory 2040 or retrieve the data therefrom.

As set forth above, in a semiconductor device according to exemplary embodiments, a plurality of semiconductor elements may be arranged on first and second substrates in a vertical direction. A seed layer for epitaxial growth may be formed on an insulating layer covering the first semiconductor elements formed on the first substrate, and the second substrate for growing the second semiconductor elements may be epitaxially grown from the seed layer, whereby the second substrate may obtain superior crystallinity and the characteristics of ground select transistors and source regions may be improved.

While exemplary embodiments have been shown and described above, it will be apparent to those skilled in the art that modifications and variations could be made without departing from the scope of the present invention as defined by the appended claims.

1.-9. (canceled)

10. A semiconductor device, comprising:
a first region including a first substrate, a plurality of first semiconductor elements on the first substrate, and an insulating layer covering the plurality of first semiconductor elements;
a second region including a second substrate on the insulating layer; and
a plurality of second semiconductor elements on the second substrate;
wherein the second substrate includes a first layer on the insulating layer and provided as a seed layer, and a second layer epitaxially grown from the seed layer; and
wherein an average diameter of a plurality of crystal grains included in the first layer is larger than a thickness of the first layer.

11. The semiconductor device of claim 10, wherein the average diameter of the plurality of crystal grains included in the first layer is smaller than an average diameter of a plurality of crystal grains included in the second layer.

12. The semiconductor device of claim 11, wherein at least some crystal grain boundaries between ones of the plurality of crystal grains included in the second layer extend from at least some crystal grain boundaries between ones of the plurality of crystal grains included in the first layer.

13. The semiconductor device of claim 10, wherein the first substrate is a single crystal silicon substrate, and
the second substrate is a polycrystalline silicon substrate.

14. The semiconductor device of claim 10, wherein the second substrate includes a pocket p-well including p-type impurities, and
a depth of the pocket p-well is less than a thickness of the second layer.

15.-16. (canceled)

17. The semiconductor device of claim 10, wherein the second layer includes a plurality of crystal grains, and
crystal grains having an angle difference about 0 to about 20 degrees between crystallization directions between adjacent crystal grains among ones of the plurality of crystal grains included in the second layer is about 40% or more.

18. The semiconductor device of claim 17, wherein a maximum value of the angle difference between the crystallization directions is equal to or less than about 70 degrees.

19. The semiconductor device of claim 10, wherein the first region is a peripheral circuit region, and
the second region is a cell region including a plurality of memory cells.

20. The semiconductor device of claim 10, wherein the first region is a cell region including a plurality of memory cells, and
the second region is a peripheral circuit region.

21. A semiconductor device, comprising:
a first substrate;
a plurality of circuit elements on the first substrate;
a second substrate above or below the first substrate and including a first layer and a second layer epitaxially grown from the first layer; and
a plurality of transistors on the second substrate to provide memory cells,
wherein an average diameter of a plurality of crystal grains included in the first layer is larger than a thickness of the first layer.

22. The semiconductor device of claim 21, wherein an average diameter of a plurality of crystal grains included in the second layer is larger than the average diameter of the plurality of crystal grains included in the first layer.

23. The semiconductor device of claim 21, wherein the plurality of transistors include:
a channel region extending in a direction perpendicular to the second substrate; and
a plurality of gate electrode layers adjacent to the channel region and stacked on the second substrate.

24. (canceled)

25. The semiconductor device of claim 21, further comprising:
a plurality of contact plugs connected to at least a portion of the plurality of circuit elements and the plurality of transistors.

26. The semiconductor device of claim 25, wherein at least one of the plurality of contact plugs penetrates through the first or second substrate.

27. A semiconductor device comprising:
a single crystalline silicon substrate;
a plurality of peripheral region circuits on the single crystalline silicon substrate;
an insulating layer on the plurality of peripheral region circuits;
a polycrystalline silicon substrate on the insulating layer, the polycrystalline silicon substrate comprising:
a first layer of the polycrystalline silicon substrate; and
an epi-second layer of the polycrystalline silicon substrate on the first layer; and
a plurality of memory cell circuits on the polycrystalline silicon substrate.

28.-29. (canceled)

30. The semiconductor device of claim 29 wherein the thickness of the epi-second layer is sufficient to provide a pocket well completely within the ep-second layer.

31. (canceled)

32. The semiconductor device of claim 27 wherein the epi-second layer comprises an epi-grown layer grown from the first layer.

33. The semiconductor device of claim 27 wherein the plurality of peripheral region circuits comprise planar peripheral region transistors and wherein the plurality of memory cell circuits comprise vertically stacked memory cell transistors.

34. The semiconductor device of claim 27 wherein an area of the polycrystalline silicon substrate is less than an area of the single crystalline silicon substrate.

35. The semiconductor device of claim 27 wherein the first layer includes polycrystalline silicon grains having a first average size; and
wherein the epi-second layer includes polycrystalline silicon grains having a second average size that is greater than the first average size.

36.-37. (canceled)
